(19) United States
(12) Patent Application Publication
(10) Pub. No.: US 2023/0352371 A1
(43) Pub. Date: Nov. 2, 2023

(54) SEMICONDUCTOR DEVICE

(71) Applicant: ROHM CO., LTD., Kyoto-shi, Kyoto (JP)

(72) Inventor: Yuki NAKANO, Kyoto-shi, Kyoto (JP)

(73) Assignee: ROHM CO., LTD., Kyoto-shi, Kyoto (JP)

(21) Appl. No.: 17/802,147

(22) PCT Filed: Apr. 30, 2021
(86) PCT No.: PCT/JP2021/017221

§ 371 Date: Aug. 25, 2022

(30) Foreign Application Priority Data
May 8, 2020 (JP) 2020-082750

(51) Int. Cl. H01L 23/485; H01L 29/423; H01L 29/78; H01L 27/12; H01L 29/739; H01L 23/00

(52) U.S. Cl. CPC H01L 23/485; H01L 29/4238; H01L 29/7815; H01L 27/1207; H01L 29/7813; H01L 29/7396; H01L 24/05; H01L 24/06; H01L 24/03; H01L 2224/45124; H01L 2224/45147; H01L 2224/45144; H01L 24/45; H01L 24/48; H01L 2224/48245; H01L 2224/4847; H01L 2224/03462; H01L 2224/03464; H01L 2224/04042; H01L 2224/05554; H01L 2224/05553; H01L 2224/05551; H01L 2224/0603; H01L 2224/06051; H01L 2224/06181; H01L 2224/05584; H01L 2224/05666; H01L 2224/05624; H01L 2224/05647; H01L 2224/05655; H01L 2224/05644; H01L 2224/05638; H01L 2924/01014; H01L 2224/05686; H01L 2924/0132; H01L 2924/0133; H01L 2924/04941; H01L 2224/05573; H01L 2224/05582; H01L 2924/10272; H01L 2924/13055; H01L 2924/13091

(57) ABSTRACT

A semiconductor device includes a semiconductor layer which has a main surface and includes SiC as a main component, a gate structure which is formed in the main surface, an insulating layer which is formed on the main surface such as to cover the gate structure, a gate main electrode which is arranged on the insulating layer and electrically connected to the gate structure, and a gate pad electrode which includes a connecting portion which is arranged on the gate main electrode such as to be connected to the gate main electrode and connected to the gate main electrode with a first area in plan view and an electrode surface having a second area exceeding the first area in plan view.

### TECHNICAL FIELD

The present application corresponds to Japanese Patent Application No. 2020-082750 filed on May 8, 2020, in the Japan Patent Office, and the entire disclosures of this application are incorporated herein by reference. The present invention relates to a semiconductor device.

### BACKGROUND ART

Patent Literature 1 discloses a semiconductor device including a gate pad which is electrically connected to a gate electrode of an IGBT. Patent Literature 2 discloses technologies relating to a vertical type semiconductor device which is provided with a semiconductor layer constituted of the SiC.

### CITATION LIST

### Patent Literature

Patent Literature 1: Japanese Patent Application Publication No. 2020-4864
Patent Literature 2: Japanese Patent Application Publication No. 2012-79945

### SUMMARY OF INVENTION

### Technical Problem

The semiconductor device according to Patent Literature 1 is provided with a gate pad for supplying electricity to a gate electrode. Wire bonding is given to the gate pad and, therefore, the gate pad is required to have at least a certain size. However, a region directly under the gate pad is a non-active region which cannot be actuated as a transistor. Therefore, there is found such a problem that when the size of the pad is secured, an actuation region (active region) which can be actuated as a transistor is narrowed.

Thus, a preferred embodiment of the present invention provides a semiconductor device capable of securing a wide actuation region.

### Solution to Problem

A preferred embodiment of the present invention provides a semiconductor device including a vertical type transistor, and the semiconductor device which is provided with a semiconductor layer having a first main surface and a second main surface on the opposite side of the first main surface and including SiC as a main component, a control electrode of the vertical type transistor which is provided on the first main surface, a first main electrode of the vertical type transistor which is provided on the first main surface, with an interval kept from the control electrode, a second main electrode of the vertical type transistor which is provided on the second main surface, a first electrode which covers a part of the first main surface, a second electrode which is provided with an interval kept from the first electrode in plan view, and a first electrode pad which overlaps with the first electrode in plan view and is electrically connected to the first electrode, in which the first electrode is smaller than the first electrode pad in plan view.

A preferred embodiment of the present invention provides a semiconductor device including a semiconductor layer which has a main surface and includes SiC as a main component, a gate structure which is formed in the main surface, an insulating layer which is formed on the main surface such as to cover the gate structure, a gate main electrode which is arranged on the insulating layer and electrically connected to the gate structure, a connecting portion which is arranged on the gate main electrode such as to be connected to the gate main electrode and which is connected to the gate main electrode with a first area in plan view, and a gate pad electrode which includes an electrode surface having a second area exceeding the first area in plan view.

A preferred embodiment of the present invention provides a semiconductor device including a semiconductor layer which has a main surface, an active region which is provided on the semiconductor layer, a non-active region of the semiconductor layer which is provided in a region outside the active region, a plurality of gate structures which are formed in the active region, an insulating layer which is formed on the main surface such as to cover the plurality of gate structures, a gate main electrode which is arranged on the insulating layer such as to be electrically connected to the plurality of gate structures and overlaps with the non-active region in plan view, and a gate pad electrode which is arranged on the gate main electrode such as to be electrically connected to the gate main electrode and overlaps with the active region and the non-active region in plan view.

The aforementioned as well as yet other objects, features and effects of the present invention will be made clear by the following description of preferred embodiments, with reference to the accompanying drawings.

### BRIEF DESCRIPTION OF DRAWINGS

FIG. 1 is a sectional view of a vertical type transistor included in a semiconductor device according to a first preferred embodiment.

FIG. 2 is a sectional view of the semiconductor device shown in FIG. 1.

FIG. 3 is a plan view of the semiconductor device shown in FIG. 1.

FIG. 4 is a plan view taken along line IV-IV shown in FIG. 2.

FIG. 5 is a plan view taken along line V-V shown in FIG. 2.

FIG. 6A is a sectional view which shows a step of a method for manufacturing the semiconductor device shown in FIG. 1.

FIG. 6B is a sectional view which shows a step subsequent to that of FIG. 6A.

FIG. 6C is a sectional view which shows a step subsequent to that of FIG. 6B.

FIG. 6D is a sectional view which shows a step subsequent to that of FIG. 6C.

FIG. 6E is a sectional view which shows a step subsequent to that of FIG. 6D.

FIG. 6F is a sectional view which shows a step subsequent to that of FIG. 6E.

FIG. 6G is a sectional view which shows a step subsequent to that of FIG. 6F.

FIG. 6H is a sectional view which shows a step subsequent to that of FIG. 6G.

FIG. 7 is a sectional view of a semiconductor device according to a second preferred embodiment.

FIG. 8 is a plan view of the semiconductor device shown in FIG. 7.

FIG. 9 is a plan view taken along line IX-IX shown in FIG. 7.

FIG. 10 is a plan view which shows a modified example of the semiconductor device according to the second preferred embodiment.

FIG. 11 is a plan view which shows an upper surface of an electrode of the semiconductor device shown in FIG. 10.

FIG. 12 is a sectional view which shows main parts of a semiconductor device according to a third preferred embodiment.

FIG. 13 is a plan view of the semiconductor device shown in FIG. 12.

FIG. 14 is a plan view taken along line XIV-XIV shown in FIG. 12.

FIG. 15 is a plan view which shows a modified example of the semiconductor device according to the third preferred embodiment.

FIG. 16 is a plan view which shows an upper surface of an electrode of the semiconductor device shown in FIG. 15.

FIG. 17 is a rear view which shows one example of a semiconductor package according to a fourth preferred embodiment.

FIG. 18 is a front view which shows an inner structure of the semiconductor package shown in FIG. 17.

FIG. 19 is a front view which shows another example of the semiconductor package according to the fourth preferred embodiment.

FIG. 20 is a sectional view which shows main parts of the semiconductor device according to a first modified example of each of the preferred embodiments described above.

FIG. 21 is a sectional view which shows main parts of the semiconductor device according to a second modified example of each of the preferred embodiments described above.

### DESCRIPTION OF EMBODIMENTS

Hereinafter, a specific description will be given of the preferred embodiments of the present invention with reference to the accompanying drawings. Each of the preferred embodiments which will be described hereinafter shows a comprehensive or specific example. A numerical value, a shape, a material, a constituent, a arranged position of the constituent, a connecting mode of the constituent, a step and a sequence of the steps shown in the preferred embodiments given below are one example and shall not restrict the present invention in any way. Of the constituents of the preferred embodiments given below, a constituent which is not described in an independent claim will be described as a given constituent.

Each of the accompanying drawings is a schematic diagram and not necessarily strictly illustrated. Therefore, in the accompanying drawings, for example, a scale, etc., are not necessarily in agreement. In the accompanying drawings, substantially the same configurations will be provided with the same reference signs and redundant descriptions will be omitted or simplified.

In this description, a term which shows a relationship between constituents such as vertical or orthogonal, a term which shows a shape of a constituent such as a rectangular shape or a rectangular parallelepiped shape and a numerical range are not expressions that indicate only strict meanings but expressions that include substantially the same range. For example, in a polygon or a polygonal column shape, an apex may be rounded.

In this description, a term such as “above” or “below” does not indicate an upper direction (perpendicularly above) or a lower direction (perpendicularly below) in an absolute spatial recognition but is used as a term that is regulated by a relative positional relationship based on a lamination sequence in a laminated configuration. Specifically, a description will be provided in such a manner that one first main surface side of a semiconductor layer is given as an upper side (above), while the other second main surface is given as a lower side (below). When a semiconductor device (a vertical type transistor) is actually used, a first main surface side may be a lower side (below) and also a second main surface side may be an upper side (above). Alternatively, the semiconductor device (the vertical type transistor) may be used in such a posture that the first main surface and the second main surface are inclined or orthogonal to a horizontal surface.

Further, the term such as “above” or “below” is applied to a case where these two constituents are arranged, with an interval kept from each other so that another constituent is interposed between two constituents, and also applied to a case where these two constituents are arranged so that two constituents are firmly attached to each other.

In this description and the drawings, an x axis, a y axis and a z axis indicate three axes of a three dimensional orthogonal coordinate system. Also, in this description, a “laminated direction” means a direction orthogonal to a main surface of a semiconductor layer. Further, “a plan view” is a view as viewed from a direction vertical to the first main surface of the semiconductor layer.

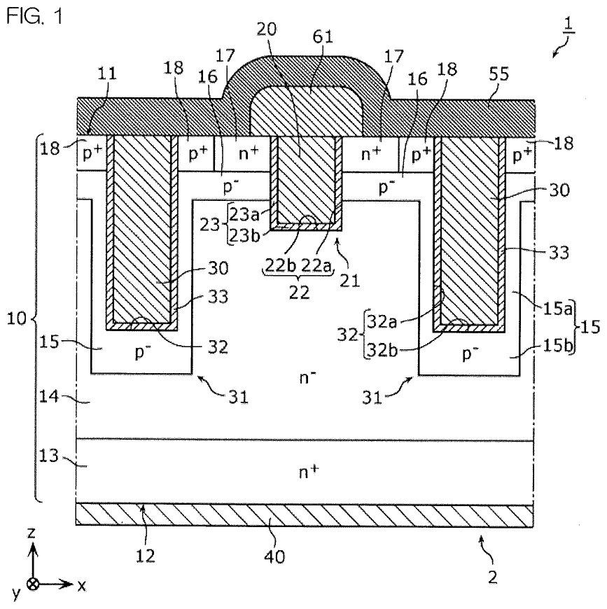

FIG. 1 is a sectional view which shows a vertical type transistor 2 included in a semiconductor device 1 according to a first preferred embodiment. In FIG. 1, in order that the drawing can be viewed easily, no hatching is shown for indicating a cross section of a semiconductor layer 10.

The semiconductor device 1 shown in FIG. 1 is one example of a switching device and includes the vertical type transistor 2. The vertical type transistor 2 is, for example, a vertical type MISFET (Metal Insulator Semiconductor Field Effect Transistor). As shown in FIG. 1, the semiconductor device 1 includes the semiconductor layer 10, a gate electrode 20, a source electrode 30 and a drain electrode 40.

The semiconductor device 1 includes the semiconductor layer 10 which includes SiC (silicon carbide) as a main component and which is one example of a wide band gap semiconductor. Specifically, the semiconductor layer 10 is an n-type SiC semiconductor layer that includes an SiC monocrystal. The SiC monocrystal is, for example, a 4H—SiC monocrystal. The 4H—SiC monocrystal has an off angle which is inclined at an angle of 10° or lower with respect to a [11-20] direction from a (0001) surface. The off angle may be not less than 0° and not more than 4°. The off angle may exceed 00 and less than 4°. The off angle is set, for example, at 20 or 4°, in a range of 2°±0.2° or in a range of 4°±0.4°.

In this preferred embodiment, the semiconductor layer 10 is formed like a chip in a rectangular parallelepiped shape. The semiconductor layer 10 has a first main surface 11 at one side and a second main surface 12 at the other side. In this preferred embodiment, the semiconductor layer 10 has a semiconductor substrate 13 and an epitaxial layer 14. The semiconductor substrate 13 is formed as an n⁺-type drain region. The epitaxial layer 14 is formed as an n⁻-type drain drift region.

The semiconductor substrate 13 includes an SiC monocrystal. A lower surface of the semiconductor substrate 13 is the second main surface 12. The second main surface 12 is a carbon surface (000-1) on which carbon of the SiC crystal is exposed. The epitaxial layer 14 is laminated on an upper surface of the semiconductor substrate 13 and is an n⁻-type SiC semiconductor layer which includes the SiC monocrystal. An upper surface of the epitaxial layer 14 is the first main surface 11. The first main surface 11 is a silicon surface (0001) on which silicon of the SiC crystal is exposed.

An n-type impurity concentration of the semiconductor substrate 13 is, for example, not less than 1.0×10¹⁸ cm⁻³ and not more than 1.0×10²¹ cm⁻³. In this description, an “impurity concentration” means a peak value of the impurity concentration. An n-type impurity concentration of the epitaxial layer 14 is lower than the n-type impurity concentration of the semiconductor substrate 13. The n-type impurity concentration of the epitaxial layer 14 is, for example, not less than 1.0×10¹⁵ cm⁻³ and not more than 1.0×10¹⁷ cm⁻³.

A thickness of the semiconductor substrate 13 is, for example, not less than 1 μm and less than 1000 μm. The thickness of the semiconductor substrate 13 may be not less than 5 μm. The thickness of the semiconductor substrate 13 may be not less than 25 μm. The thickness of the semiconductor substrate 13 may be not less than 50 μm. The thickness of the semiconductor substrate 13 may be not less than 100 μm.

The thickness of the semiconductor substrate 13 may be not more than 700 μm. The thickness of the semiconductor substrate 13 may be not more than 500 μm. The thickness of the semiconductor substrate 13 may be not more than 400 μm. The thickness of the semiconductor substrate 13 may be not more than 300 μm. The thickness of the semiconductor substrate 13 may be not more than 250 μm. The thickness of the semiconductor substrate 13 may be not more than 200 μm. The thickness of the semiconductor substrate 13 may be not more than 150 μm. The thickness of the semiconductor substrate 13 may be not more than 100 μm. In the vertical type transistor 2, a current flows in a thickness direction of the semiconductor substrate 13 (that is, a laminated direction). Therefore, the thickness of the semiconductor substrate 13 is reduced, thus making it possible to realize a reduction in resistance value by a shortened current path.

A thickness of the epitaxial layer 14 is, for example, not less than 1 μm and not more than 100 μm. The thickness of the epitaxial layer 14 may be not less than 5 μm. The thickness of the epitaxial layer 14 may be not less than 10 μm. The thickness of the epitaxial layer 14 may be not more than 50 μm. The thickness of the epitaxial layer 14 may be not more than 40 μm. The thickness of the epitaxial layer 14 may be not more than 30 μm. The thickness of the epitaxial layer 14 may be not more than 20 μm. The thickness of the epitaxial layer 14 may be not more than 15 μm. The thickness of the epitaxial layer 14 may be not more than 10 μm.

The semiconductor device 1 includes a plurality of trench gate structures 21 and a plurality of trench source structures 31, each of which is formed in the first main surface 11 of the semiconductor layer 10. The trench gate structures 21 and the trench source structures 31 are arranged one by one alternately and repeatedly along an x axis direction in plan view to form a stripe structure. In FIG. 1, there is shown only a range in which one trench gate structure 21 is held between two trench source structures 31.

Each of the trench gate structures 21 and the trench source structures 31 is formed in a band shape extending along a y axis direction. For example, the x axis direction is a [11-20] direction and the y axis direction is a [1-100] direction. The x axis direction may be a [−1100] direction ([1-100] direction). In this case, the y axis direction may be the [11-20] direction. A distance between the trench gate structure 21 and the trench source structure 31 is, for example, not less than 0.3 μm and not more than 1.0 μm.

As shown in FIG. 1, the trench gate structure 21 includes a gate trench 22, a gate insulating layer 23 and a gate electrode 20. The gate trench 22 is formed by digging the first main surface 11 of the semiconductor layer 10 toward the second main surface 12 side. The gate trench 22 has a rectangular cross-sectional shape on an xz cross section and is a groove-shaped recessed portion extending in a band shape along the y axis direction.

The gate trench 22 may have a length on the order millimeters in a longitudinal direction (the y axis direction). The gate trench 22 has a length of, for example, not less than 1 mm and not more than 10 mm. The length of the gate trench 22 may be not less than 2 mm and not more than 5 mm. A total extension of one or the plurality of gate trenches 22 per unit area may be not less than 0.5 μm/μm² and not more than 0.75 μm/μm².

The gate insulating layer 23 is provided in a film shape along a side wall 22a and a bottom wall 22b of the gate trench 22. The gate insulating layer 23 demarcates a recessed space inside the gate trench 22. The gate insulating layer 23 includes, for example, silicon oxide. The gate insulating layer 23 may include at least one type of impurity-free silicon, silicon nitride, aluminum oxide, aluminum nitride and aluminum oxynitride.

A thickness of the gate insulating layer 23 is, for example, not less than 0.01 μm and not more than 0.5 μm. The gate insulating layer 23 may be uniform or may be different in thickness, depending on a site. For example, the gate insulating layer 23 includes a side wall portion 23a and a bottom wall portion 23b. The side wall portion 23a is formed along the side wall 22a of the gate trench 22. The bottom wall portion 23b is formed along the bottom wall 22b of the gate trench 22.

A thickness of the bottom wall portion 23b may be larger than a thickness of the side wall portion 23a. The thickness of the bottom wall portion 23b is, for example, not less than 0.01 μm and not more than 0.2 μm. The thickness of the side wall portion 23a is, for example, not less than 0.05 μm and not more than 0.5 μm. Further, the gate insulating layer 23 may include an upper surface portion which is formed on an upper surface of the first main surface 11 outside the gate trench 22. A thickness of the upper surface portion may be thicker than the thickness of the side wall portion 23a.

The gate electrode 20 is one example of a control electrode of the vertical type transistor 2. The gate electrode 20 is embedded into the gate trench 22. The gate insulating layer 23 is provided between the gate electrode 20 and the side wall 22a and the bottom wall 22b of the gate trench 22. That is, the gate electrode 20 is embedded into a recessed space demarcated by the gate insulating layer 23. The gate electrode 20 is a conductive layer which includes, for example, conductive polysilicon. The gate electrode 20 may include at least one type of metal such as titanium, nickel, copper, aluminum, silver, gold and tungsten or conductive metal nitrides such as titanium nitride.

A width of the trench gate structure 21 is, for example, not less than 0.2 μm and not more than 2.0 μm. As an example, the width of the trench gate structure 21 may be about 0.4 μm. A depth of the trench gate structure 21 is, for example, not less than 0.5 μm and not more than 3.0 μm. As an example, the depth of the trench gate structure 21 may be about 1.0 μm.

An aspect ratio of the trench gate structure 21 is, for example, not less than 0.25 and not more than 15.0. The aspect ratio of the trench gate structure 21 is defined by a ratio of the depth of the trench gate structure 21 (a length in the z axis direction) with respect to the width of the trench gate structure 21 (a length in the x axis direction). In this preferred embodiment, the aspect ratio of the trench gate structure 21 is the same as the aspect ratio of the gate trench 22.

As shown in FIG. 1, the trench source structure 31 includes a source trench 32, a deep well region 15, a barrier forming layer 33 and a source electrode 30. The source trench 32 is formed by digging the first main surface 11 of the semiconductor layer 10 toward the second main surface 12 side. The source trench 32 has a rectangular cross-sectional shape in an xz cross section and is a groove-shaped recessed portion extending in a band shape along the y axis direction. In this preferred embodiment, the source trench 32 is deeper than the gate trench 22. That is, a bottom wall 32b of the source trench 32 is at a position which is closer to the second main surface 12 side than the bottom wall 22b of the gate trench 22.

The deep well region 15 is formed in a region of the semiconductor layer 10 along the source trench 32. The deep well region 15 is also referred to as a withstand voltage retaining region. The deep well region 15 is a p⁻-type semiconductor region. A p-type impurity concentration of the deep well region 15 is, for example, not less than 1.0×10¹⁷ cm⁻³ and not more than 1.0×10¹⁹ cm⁻³. The p-type impurity concentration of the deep well region 15 is, for example, higher than the n-type impurity concentration of the epitaxial layer 14.

The deep well region 15 includes a side wall portion 15a along a side wall 32a of the source trench 32 and a bottom wall portion 15b along the bottom wall 32b of the source trench 32. A thickness of the bottom wall portion 15b (a length in the z axis direction) is, for example, not less than the thickness of the side wall portion 15a (a length in the x axis direction). At least a part of the bottom wall portion 15b may be positioned inside the semiconductor substrate 13.

The source electrode 30 is one example of the first main electrode of the vertical type transistor 2. The source electrode 30 is embedded into the source trench 32. The source electrode 30 is a conductive layer which includes, for example, conductive polysilicon. The source electrode 30 may be n-type polysilicon to which an n-type impurity is added or p-type polysilicon to which a p-type impurity is added. The source electrode 30 may include at least one type of metal such as titanium, nickel, copper, aluminum, silver, gold and tungsten or conductive metal nitrides such as titanium nitride. The source electrode 30 may be formed with the same material as the gate electrode 20. In this case, the source electrode 30 and the gate electrode 20 are formed in the same step.

The barrier forming layer 33 is interposed between the source electrode 30 and the source trench 32. The barrier forming layer 33 is formed in a film shape along the side wall 32a and the bottom wall 32b of the source trench 32 between the source electrode 30 and the source trench 32. That is, the source electrode 30 is embedded into a recessed space demarcated by the barrier forming layer 33. The barrier forming layer 33 demarcates the recessed space inside the source trench 32. The barrier forming layer 33 is formed with a material different from that of the source electrode 30. The barrier forming layer 33 has a potential barrier higher than a potential barrier between the source electrode 30 and the deep well region 15.

The barrier forming layer 33 may be an insulating barrier forming layer. In this case, the barrier forming layer 33 includes at least one type of impurity-free silicon, silicon oxide, silicon nitride, aluminum oxide, aluminum nitride and aluminum oxynitride. The barrier forming layer 33 may be formed with the same material as the gate insulating layer 23. In this case, the barrier forming layer 33 may have the same film thickness as the gate insulating layer 23. For example, the barrier forming layer 33 and the gate insulating layer 23 may be formed with silicon oxide. In this case, the barrier forming layer 33 and the gate insulating layer 23 are formed at the same time by a thermal oxidation treatment method.

The barrier forming layer 33 may be a conductive barrier forming layer. In this case, the barrier forming layer 33 includes at least one type of conductive polysilicon, tungsten, platinum, nickel, cobalt and molybdenum.

A width of the trench source structure 31 is, for example, not less than 0.6 μm and not more than 2.4 μm. As an example, the width of the trench source structure 31 may be about 0.8 μm. A depth of the trench source structure 31 is a sum of the depth of the source trench 32 and the thickness of the bottom wall portion 15b of the deep well region 15. The depth of the trench source structure 31 is, for example, not less than 1.5 μm and not more than 11 μm. As an example, the depth of the trench source structure 31 may be about 2.5 μm.

An aspect ratio of the trench source structure 31 is larger than an aspect ratio of the trench gate structure 21. The aspect ratio of the trench source structure 31 is defined by a ratio of the depth of the trench source structure 31 (a length in the z axis direction) with respect to the width of the trench source structure 31 (a length in the x axis direction). In this preferred embodiment, the width of the trench source structure 31 is a sum of the width of the source trench 32 and widths of the side wall portions 15a of the deep well region 15 positioned on the both sides of the source trench 32. For example, the aspect ratio of the trench source structure 31 is not less than 1.5 and not more than 4.0. The depth of the trench source structure 31 is enlarged, thus making it possible to enhance the withstand voltage retaining effects by an SJ (Super Junction) structure.

As shown in FIG. 1, the semiconductor device 1 includes a body region 16, a source region 17 and a contact region 18, each of which is formed in the epitaxial layer 14 of the semiconductor layer 10. The deep well region 15, the body region 16, the source region 17 and the contact region 18 which have been described above may be regarded as constituents of the epitaxial layer 14.

The body region 16 is a p⁻-type semiconductor region which is provided at a surface layer portion of the first main surface 11 of the semiconductor layer 10. The body region 16 is formed at a region between the gate trench 22 and the source trench 32 in plan view. The body region 16 is formed in a band shape extending along the y axis direction in plan view. The body region 16 continues to the deep well region 15.

A p-type impurity concentration of the body region 16 is, for example, not less than 1.0×10¹⁶ cm⁻³ and not more than 1.0×10¹⁹ cm⁻³. The p-type impurity concentration of the body region 16 may be equal to that of an impurity region of the deep well region 15. The p-type impurity concentration of the body region 16 may be higher than the p-type impurity concentration of the deep well region 15.

The source region 17 is an n⁺-type semiconductor region which is provided at a surface layer portion of the first main surface 11 of the semiconductor layer 10 in the body region 16. The source region 17 is provided at a region along the gate trench 22. The source region 17 is in contact with the gate insulating layer 23 and opposes the gate electrode 20 across the gate insulating layer 23. Specifically, the source region 17 is in contact with the side wall portion 23a of the gate insulating layer 23. The source region 17 may be in contact with an upper surface portion of the gate insulating layer 23.

The source region 17 is formed in a band shape extending along the y axis direction in plan view. A width of the source region 17 (a length in the x axis direction) is, for example, not less than 0.2 μm and not more than 0.6 μm. As an example, the width of the source region 17 may be about 0.4 μm. An n-type impurity concentration of the source region 17 is, for example, not less than 1.0×10¹⁸ cm⁻³ and not more than 1.0×10²¹ cm⁻³.

The contact region 18 is a p⁺-type semiconductor region which is provided at a surface layer portion of the first main surface 11 of the semiconductor layer 10. The contact region 18 may be regarded as a part of the body region 16 (a high concentration part). The contact region 18 is formed in a region which is along the source trench 32. The contact region 18 is in contact with the barrier forming layer 33 and opposes the source electrode 30 across the barrier forming layer 33. The contact region 18 is electrically connected to the body region 16. The contact region 18 is electrically connected to the source region 17.

The contact region 18 is formed in a band shape extending along the y axis direction in plan view. A width of the contact region 18 (a length in the x axis direction) is, for example, not less than 0.1 μm and not more than 0.4 μm. As an example, the width of the contact region 18 may be about 0.2 μm. A p-type impurity concentration of the contact region 18 is, for example, not less than 1.0×10¹⁸ cm⁻³ and not more than 1.0×10²¹ cm⁻³.

The semiconductor device 1 includes a drain electrode 40 which is connected to the second main surface 12 of the semiconductor layer 10. The drain electrode 40 is one example of a second main electrode of the semiconductor device 1 (the vertical type transistor 2). The drain electrode 40 may include at least one type of titanium, nickel, copper, aluminum, gold and silver. For example, the drain electrode 40 may have a four layer structure which includes a Ti layer, an Ni layer, an Au layer, an Ag layer laminated in sequence from the second main surface 12 of the semiconductor layer 10.

The drain electrode 40 may have a four layer structure which includes a Ti layer, an AlCu layer, an Ni layer and an Au layer laminated in sequence from the second main surface 12 of the semiconductor layer 10. The AlCu layer is an alloy layer of aluminum and copper. The drain electrode 40 may have a four layer structure which includes a Ti layer, an AlSiCu layer, an Ni layer and an Au layer laminated in sequence from the second main surface 12 of the semiconductor layer 10. The AlSiCu layer is an alloy layer of aluminum, silicon and copper. The drain electrode 40 may include a single layer structure having a TiN layer in place of a Ti layer or a laminated structure having a Ti layer and a TiN layer.

In the semiconductor device 1 constituted as described so far, an on state in which a drain current flows or an off state in which no drain current flows can be switched, depending on a gate voltage applied to the gate electrode 20 of the vertical type transistor 2. The gate voltage is a voltage of, for example, not less than 10V and not more than 50V. As an example, the gate voltage may be 30V. A source voltage applied to the source electrode 30 is, for example, a reference voltage such as a ground voltage (0V). A drain voltage applied to the drain electrode 40 is equal to or higher than the source voltage. The drain voltage is, for example, not less than 0V and not more than 10000V. The drain voltage may be not less than 1000V.

Where the gate voltage is applied to the gate electrode 20, a channel is formed at a portion in contact with the gate insulating layer 23 of the p⁻-type body region 16. Thereby, a current path through a channel of the body region 16 is formed between the source electrode 30 and the drain electrode 40. The current path connects the contact region 18, the source region 17, the channel of the body region 16, the epitaxial layer 14, and the semiconductor substrate 13 between the source electrode 30 and the drain electrode 40.

The drain electrode 40 may be higher in potential than the source electrode 30. In this case, a drain current flows from the drain electrode 40 to the source electrode 30. That is, the drain region flows to the source electrode 30, passing through the drain electrode 40, the semiconductor substrate 13, the epitaxial layer 14, the channel of the body region 16, the source region 17 and the contact region 18 in this order. As described so far, the drain current flows along a thickness direction of the semiconductor device 1.

In this preferred embodiment, a pn junction portion (pn junction) is formed between a p⁻-type deep well region 15 and an n⁻-type epitaxial layer 14. In an on state of the vertical type transistor 2, the source voltage is applied to the p⁻-type deep well region 15 through the source electrode 30 and the drain voltage higher than the source voltage is applied to the n⁻-type epitaxial layer 14 through the drain electrode 40.

That is, a reverse bias voltage is applied to the pn junction portion between the deep well region 15 and the epitaxial layer 14. Therefore, a depletion layer spreads to the drain electrode 40 from an interface portion (interface) between the deep well region 15 and the epitaxial layer 14. Thereby, it is possible to enhance a withstand voltage of the vertical type transistor 2.

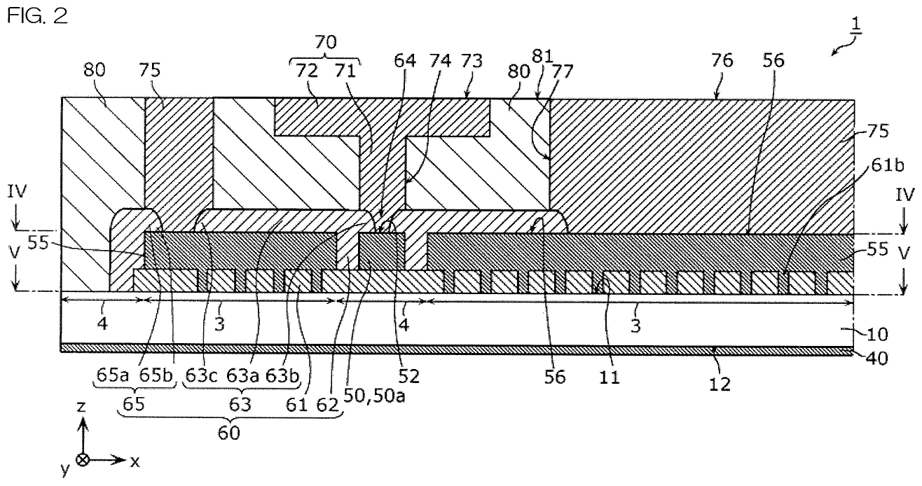

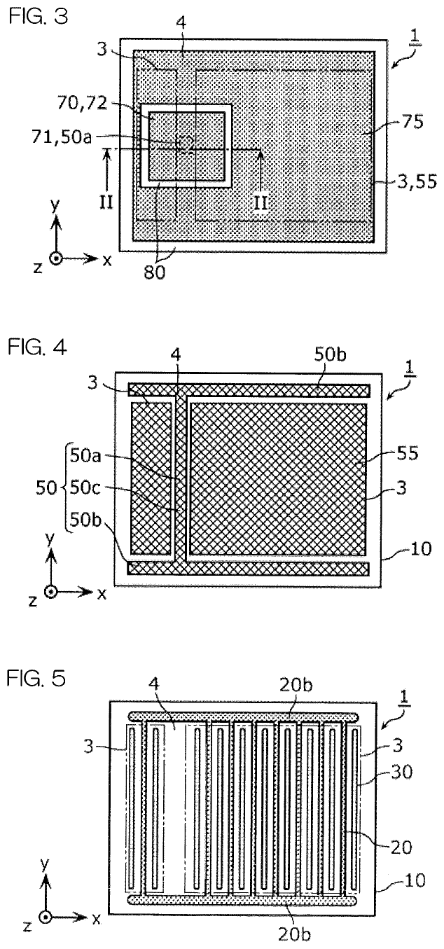

Next, a description will be given of a pad structure for supplying a predetermined voltage to the gate electrode 20 and the source electrode 30. FIG. 2 is a sectional view of the semiconductor device 1 shown in FIG. 1. FIG. 3 is a plan view of the semiconductor device 1 shown in FIG. 1. Specifically, FIG. 2 is a sectional view taken along line II-II shown in FIG. 3. In FIG. 2, illustration of a specific configuration of the semiconductor layer 10 shown in FIG. 1 is omitted. Further, in FIG. 2, no hatching is shown for a cross section of the semiconductor layer 10.

As shown in FIG. 2 and FIG. 3, the semiconductor device 1 includes a main surface gate electrode 50, a main surface source electrode 55, an insulating layer 60, a gate pad 70, a source pad 75 and a mold layer 80. The pad structure is provided above the first main surface 11 of the semiconductor layer 10.

FIG. 4 is a plan view taken along line IV-IV shown in FIG. 2. Specifically, FIG. 4 is a plan view when the semiconductor device 1 is viewed from the positive side of the z axis through the gate pad 70, the source pad 75 and the mold layer 80 shown in FIG. 3. For example, the positive side of the z axis is the first main surface 11 side on the assumption that the second main surface 12 (or the front surface of the drain electrode 40) is positioned on an xy plane of z=0. Specifically, FIG. 5 is a plan view when the semiconductor device 1 is viewed from the positive side of the z axis through the main surface gate electrode 50, the main surface source electrode 55 and the insulating layer 60 individually shown in FIG. 4 as well as the gate pad 70, the source pad 75 and the mold layer 80 individually shown in FIG. 3.

As shown in FIG. 3 to FIG. 5, the semiconductor layer 10 (the semiconductor device 1) has a rectangular planar shape. In plan view, a length of one side of the semiconductor layer 10 (the semiconductor device 1) is, for example, not less than 1 mm and not more than 10 mm. In plan view, the length of one side of the semiconductor layer 10 (the semiconductor device 1) may be not less than 2 mm and not more than 5 mm.

The semiconductor device 1 includes an active region 3 and a non-active region 4 (an outer region). In FIG. 3 and FIG. 5, the active region 3 is shown by two-dot chain lines. The active region 3 is a main region through which a drain current of the vertical type transistor 2 flows. That is, the active region 3 is an actuation region of the vertical type transistor 2. Specifically, the active region 3 is substantially in agreement with a region covered by the main surface source electrode 55.

In this preferred embodiment, the active region 3 is separated into a region of the semiconductor layer 10 at one side (the left side of the paper) in the x axis direction and a region thereof at the other side (the right side of the paper) in the x axis direction in plan view. In the active region 3, a plane area of the region at one side (the left side of the paper) may be different from a plane area of the region at the other side (the right side of the paper). In this preferred embodiment, there is shown an example in which the plane area of the region at one side (the left side of the paper) is less than the plane area of the region at the other side (the right side of the paper).

As shown in FIG. 5, the active region 3 includes the plurality of gate electrodes 20 (trench gate structures 21) and the plurality of source electrodes 30 (trench source structures 31). In FIG. 5, the plurality of gate electrodes 20 and the plurality of source electrodes 30 are schematically illustrated to such an extent that the number of gate electrodes 20 and that of the source electrodes 30 can be counted. However, the number of gate electrodes 20 and that of the source electrodes 30 are in reality much larger than the number illustrated.

The non-active region 4 is a region which is not actuated as the vertical type transistor 2. The non-active region 4 is a frame-shaped (annular) region which surrounds the active region 3. In this preferred embodiment, the non-active region 4 separates the active region 3 into a region at one side (the left side of the paper) and a region at the other side (the right side of the paper). That is, the non-active region 4 surrounds the region of the active region 3 at one side (the left side of the paper) in plan view. Further, the non-active region 4 surrounds the region of the active region 3 at one side (the left side of the paper) in plan view.

As shown in FIG. 5, a gate finger portion 20b which is to be described later is provided in the non-active region 4. In the examples shown in FIG. 3 to FIG. 5, although the active region 3 is separated into two portions by the non-active region 4, the active region 3 may be a single region which is not separated. The active region 3 can be appropriately adjusted for the shape and disposition by layout of the gate finger portion 20b.

As shown in FIG. 4, the active region 3 is included in a region which is covered by the main surface source electrode 55. As shown in FIG. 3, the active region 3 includes a part of a region covered by the gate pad 70. The region covered by the main surface gate electrode 50 is included in the non-active region 4 and not included in the active region 3.

The main surface gate electrode 50 is one example of a first electrode which covers a part of the first main surface 11. The main surface gate electrode 50 includes, for example, at least one type of metal such as conductive polysilicon, titanium, nickel, copper, aluminum, silver, gold and tungsten or metal nitrides such as titanium nitride. The main surface gate electrode 50 may be formed with the same material as the gate electrode 20.

The main surface gate electrode 50 is electrically connected to the gate electrode 20. As shown in FIG. 2, the main surface gate electrode 50 is provided in a line on the insulating layer 60 which is to be described later (specifically, a lower insulating layer 61 which is to be described later). The main surface gate electrode 50 is connected to the gate electrode 20 (not shown in FIG. 2) through a via conductor which penetrates through the insulating layer 60 (specifically, the lower insulating layer 61).

As shown in FIG. 4, the main surface gate electrode 50 includes an electricity receiving portion 50a, an electricity supplying portion 50b and a connecting portion 50c. The electricity receiving portion 50a of the main surface gate electrode 50 is provided in an inner portion of the first main surface 11 in plan view. Specifically, the electricity receiving portion 50a is provided on a region positioned between the region of the active region 3 at one side (the left side of the paper) and the region thereof at the other side (the right side of the paper) in the non-active region 4 in plan view.

The electricity receiving portion 50a is positioned directly under the gate pad 70 which is to be described later and is a portion connected to the gate pad 70 (specifically, a columnar shaped portion 71 which is to be described later). In plan view, a portion of the main surface gate electrode 50 which overlaps with the columnar shaped portion 71 corresponds to the electricity receiving portion 50a. The electricity receiving portion 50a of the main surface gate electrode 50 is smaller than the gate pad 70 in plan view. A planar shape of the electricity receiving portion 50a (a planar shape of the columnar shaped portion 71) is, for example, square or rectangular. A length of one side of the electricity receiving portion 50a is not less than 5 μm and not more than 50 μm. As an example, the planar shape of the electricity receiving portion 50a may be square of about 20 μm×20 μm.

The electricity supplying portion 50b is a portion which extends along an outer periphery of the semiconductor layer 10 (a peripheral edge of the first main surface 11) in plan view. In the example shown in FIG. 4, the electricity supplying portion 50b extends along the x axis direction of the semiconductor layer 10. In this preferred embodiment, the two electricity supplying portions 50b are provided so that an inner portion of the first main surface 11 is held therebetween from the positive side and the negative side of the y axis direction in plan view. The electricity supplying portion 50b may be provided such as to surround the inner portion of the first main surface 11 (for example, the main surface source electrode 55 which is to be described later) around an entire periphery of the semiconductor layer 10.

The connecting portion 50c is a portion which is connected to the electricity receiving portion 50a and the electricity supplying portion 50b. In the example shown in FIG. 4, the connecting portion 50c is drawn out from the electricity receiving portion 50a to each of the positive side and the negative side of the y axis direction such as to be connected to the electricity supplying portion 50b and extends up to the electricity supplying portion 50b. A region in which the electricity receiving portion 50a, the electricity supplying portion 50b and the connecting portion 50c are provided is non-active region 4. Therefore, the electricity receiving portion 50a, the electricity supplying portion 50b and the connecting portion 50c are preferably formed such as to be as small as possible.

In this preferred embodiment, the main surface gate electrode 50 is electrically connected to each of the plurality of gate electrodes 20 through the electricity supplying portion 50b. Specifically, a through hole is provided at the insulating layer 60 to be described later which is positioned directly under the electricity supplying portion 50b (specifically, the lower insulating layer 61 which is to be described later), and the electricity supplying portion 50b is connected through the through hole to the gate finger portion 20b which is to be described later (refer to FIG. 5).

As shown in FIG. 5, the plurality of gate electrodes 20 (the trench gate structures 21) are formed in a longitudinal shape extending in the y axis direction. The plurality of gate electrodes 20 may be separated into a portion on the positive side of the y axis direction and a portion on the negative side thereof at a central portion in the y axis direction.

As shown in FIG. 5, the semiconductor device 1 includes the gate finger portion 20b which is formed on the semiconductor layer 10 (the first main surface 11) such as to be electrically connected to the plurality of gate electrodes 20. Specifically, the gate finger portion 20b is interposed between the semiconductor layer 10 (the first main surface 11) and the insulating layer 60 which is to be described later. The gate finger portion 20b extends in the x axis direction along a peripheral edge of the first main surface 11 (an outer periphery of the semiconductor device 1) in plan view.

In this preferred embodiment, the two gate finger portions 20b are provided so that the plurality of gate electrodes 20 are held therebetween from the positive side and the negative side of the y axis direction in plan view. The gate finger portion 20b is connected to both ends of the plurality of gate electrodes 20 in the y axis direction. The gate finger portion 20b may be connected only to one end of the plurality of gate electrodes 20 in the y axis direction. The above-described electricity supplying portion 50b is connected to the gate finger portion 20b through the through hole provided on the insulating layer 60 which is to be described later (specifically, the lower insulating layer 61 which is to be described later).

The main surface source electrode 55 is one example of a second electrode which covers a part of the first main surface 11. The main surface source electrode 55 is provided with an interval kept from the main surface gate electrode 50, in plan view. The main surface source electrode 55 is formed in plan view, for example, in a region of the first main surface 11 of the semiconductor layer 10 (the semiconductor device 1) in which the main surface gate electrode 50 is provided and in a substantially entire region excluding a periphery of the region concerned. The main surface source electrode 55 is larger than the main surface gate electrode 50 in plan view.

Specifically, the main surface source electrode 55 includes a first portion which is arranged on a region of the active region 3 at one side (the left side of the paper) and a second portion which is arranged on a region of the active region 3 at the other side (the right side of the paper) separated from the first portion. A plane area of the second portion is larger than a first plane area of the first portion. A total value of the plane area of the first portion and the plane area of the second portion is larger than the plane area of the main surface gate electrode 50.

The main surface source electrode 55 includes, for example, at least one type of metal such as conductive polysilicon, titanium, nickel, copper, aluminum, silver, gold and tungsten or metal nitrides such as titanium nitride. The main surface source electrode 55 may be formed with the same material as the source electrode 30. The main surface source electrode 55 may be formed with the same material as the main surface gate electrode 50. In this case, the main surface gate electrode 50 and the main surface source electrode 55 can be formed in the same step.

The plurality of source electrodes 30 are provided directly under the main surface source electrode 55, and the main surface source electrode 55 is electrically connected to the source electrode 30. Therefore, as shown in FIG. 1, the main surface source electrode 55 is directly connected to an upper surface of each of the plurality of source electrodes 30. As shown in FIG. 2, a lower portion of the main surface source electrode 55 is given as the active region 3 and the MOSFET structure shown in FIG. 1 is formed regularly in the active region 3.

The main surface source electrode 55 has an area which is not less than 50% of an area of the semiconductor layer 10 (the first main surface 11) in plan view. Preferably, the main surface source electrode 55 has an area which is not less than 70% of the area of the semiconductor layer 10 (the first main surface 11) in plan view. On the other hand, the main surface gate electrode 50 has an area which is not more than 20% of the area of the semiconductor layer 10 (the first main surface 11) in plan view. Preferably, the main surface gate electrode 50 has an area which is not more than 10% of the area of the semiconductor layer 10 (the first main surface 11) in plan view.

The main surface source electrode 55 is arranged in a region which includes a central position of the semiconductor layer 10 (the first main surface 11) in plan view. The main surface gate electrode 50 is arranged in a region away from the main surface source electrode 55. The main surface gate electrode 50 may be arranged in a region which includes the central position of the semiconductor layer 10 (the first main surface 11). In this case, the main surface source electrode 55 may be arranged such as to surround a periphery of the main surface gate electrode 50.

As shown in FIG. 2, the insulating layer 60 includes a lower insulating layer 61, a side insulating layer 62, an upper insulating layer 63 and an end insulating layer 65. In FIG. 4, a hatching-free portion of the periphery of the main surface gate electrode 50 corresponds to the side insulating layer 62 and the end insulating layer 65. The lower insulating layer 61 is an inter-layer insulating film and provided on the first main surface 11. Specifically, the lower insulating layer 61 collectively covers the plurality of trench gate structures 21. As shown in FIG. 1, the lower insulating layer 61 is provided for the purpose of preventing a contact with the main surface source electrode 55 and the gate electrode 20.

The lower insulating layer 61 has a plurality of source contact holes 61b. A part of the main surface source electrode 55 is embedded into the plurality of source contact holes 61b. Thereby, the main surface source electrode 55 is electrically connected to the plurality of source electrodes 30 inside the plurality of source contact holes 61b.

Although not shown in FIG. 2, as described above, a through hole for connecting the electricity supplying portion 50b of the main surface gate electrode 50 (refer to FIG. 4) to the gate finger portion 20b (refer to FIG. 5) is provided in the lower insulating layer 61. A part of the electricity supplying portion 50b is embedded into the through hole of the lower insulating layer 61. The electricity supplying portion 50b is connected to the gate finger portion 20b inside the through hole. Thereby, the main surface gate electrode 50 is electrically connected to the gate electrode 20.

The side insulating layer 62 is formed on the lower insulating layer 61 and provided for the purpose of preventing a contact of the main surface gate electrode 50 with the main surface source electrode 55. As shown in FIG. 4, the side insulating layer 62 is provided such as to surround the main surface gate electrode 50.

The upper insulating layer 63 is formed on an upper surface 56 of the main surface source electrode 55. Specifically, the upper insulating layer 63 covers a portion which is along the electricity receiving portion 50a of the main surface gate electrode 50 on the main surface source electrode 55. The upper insulating layer 63 covers a part of the electricity receiving portion 50a such as to partially expose the upper surface 52 of the electricity receiving portion 50a. That is, the upper insulating layer 63 has a through hole 64 which exposes the upper surface 52 of the electricity receiving portion 50a. As shown in FIG. 2, a part of the upper insulating layer 63 runs onto the electricity receiving portion 50a from above the lower insulating layer 61.

More specifically, the upper insulating layer 63 includes a flat portion 63a, a first end portion 63b and a second end portion 63c. The flat portion 63a is provided on the upper surface 56 of the main surface source electrode 55 and it is a portion which is substantially uniform in thickness. A part of the flat portion 63a is provided on the upper surface 52 of the electricity receiving portion 50a as well.

The first end portion 63b is provided on the upper surface 52 of the electricity receiving portion 50a of the main surface gate electrode 50. The second end portion 63c is provided on the upper surface 56 of the main surface source electrode 55. Each of the first end portion 63b and the second end portion 63c is a portion which is not uniform in thickness. Each of the first end portion 63b and the second end portion 63c is inclined, for example, such as to be gradually decreased in thickness. The first end portion 63b and the second end portion 63c may have an inclined surface with a certain inclination angle and may also have a curved surface which is curved in a raised shape or in a recessed shape.

In plan view, the size and the shape of the through hole 64 are substantially in agreement with the size and the shape of the electricity receiving portion 50a of the main surface gate electrode 50. Specifically, a part of the upper insulating layer 63 runs onto the electricity receiving portion 50a and, therefore, the size of the through hole 64 is smaller than the electricity receiving portion 50a in plan view.

The end insulating layer 65 is provided on the first main surface 11 along an outer periphery of the main surface source electrode 55. The end insulating layer 65 is formed, for example, in an annular shape such as to cover an entire periphery of the main surface source electrode 55 in plan view. As shown in FIG. 2, the end insulating layer 65 has a portion which runs onto the lower insulating layer 61 and an electrode covering portion which runs onto the main surface source electrode 55 (the upper surface 56).

The electrode covering portion of the end insulating layer 65 has a flat portion 65a and an end portion 65b. The flat portion 65a is a portion which is substantially uniform in thickness. The end portion 65b is a portion which is not uniform in thickness. The end portion 65b is inclined, for example, such as to be gradually decreased in thickness. The end portion 65b may have an inclined surface with a certain inclination angle and may also have a curved surface which is curved in a raised shape or in a recessed shape. The end insulating layer 65 may cover the electricity supplying portion 50b of the main surface gate electrode 50 shown in FIG. 4.

The lower insulating layer 61 includes, for example, silicon oxide or silicon nitride as a main component. The lower insulating layer 61, the side insulating layer 62, the upper insulating layer 63 and the end insulating layer 65 may include PSG (Phosphor Silicate Glass) and/or BPSG (Boron Phosphor Silicate Glass) as one example of silicon oxide.

The side insulating layer 62, the upper insulating layer 63 and the end insulating layer 65 may each include a photosensitive resin. The side insulating layer 62, the upper insulating layer 63 and the end insulating layer 65 may be each constituted of an organic material such as polyimide and PBO (polybenzoxazole). A thickness of the upper insulating layer 63 and that of the end insulating layer 65 are, for example, not less than 3 μm and not more than 20 μm. The thickness of the upper insulating layer 63 and that of the end insulating layer 65 may be preferably not less than 5 μm and not more than 15 μm. The thickness of the upper insulating layer 63 and that of the end insulating layer 65 may be more preferably not less than 5 μm and not more than 10 μm. The lower insulating layer 61, the side insulating layer 62, the upper insulating layer 63 and the end insulating layer 65 may be formed with the same insulating material (for example, an inorganic insulating material such as silicon oxide and silicon nitride).

The gate pad 70 is one example of the first electrode pad. The gate pad 70 overlaps with the main surface gate electrode 50 in plan view and is electrically connected to the main surface gate electrode 50. The gate pad 70 completely covers the electricity receiving portion 50a of the main surface gate electrode 50. That is, in plan view, the electricity receiving portion 50a of the main surface gate electrode 50 is positioned inside the gate pad 70.

The gate pad 70 overlaps with a part of the main surface source electrode 55 in plan view. That is, the part of the main surface source electrode 55 is positioned directly under the gate pad 70. In this preferred embodiment, the main surface source electrode 55 is drawn out to a region which overlaps with the gate pad 70 in plan view and, therefore, a part of the region in which the gate pad 70 overlaps with the main surface source electrode 55 can be used as the active region 3. Thereby, it is possible to secure a larger area of the active region 3, while securing an area of the gate pad 70.

As shown in FIG. 2, the gate pad 70 includes a columnar shaped portion 71 and a wide portion 72. The columnar shaped portion 71 is one example of the first conductive layer provided on the main surface gate electrode 50. The columnar shaped portion 71 extends in a columnar shape in a normal direction (the z axis direction) of the upper surface 52 of the electricity receiving portion 50a of the main surface gate electrode 50.

The columnar shaped portion 71 covers the upper surface 52 of the electricity receiving portion 50a. Further, the columnar shaped portion 71 covers a part of the flat portion 63a of the upper insulating layer 63 and the first end portion 63b. A height of the columnar shaped portion 71 (a length in the z axis direction) is larger (longer) than a thickness of the upper insulating layer 63 (a length in the z axis direction). Specifically, the height of the columnar shaped portion 71 is larger (longer) than a maximum thickness of a portion of the upper insulating layer 63 positioned on the electricity receiving portion 50a. Thereby, a top of the columnar shaped portion 71 is higher than a top of the upper insulating layer 63.

The columnar shaped portion 71 has a side surface 74 which extends vertically or substantially vertically. The side surface 74 is not necessarily required to extend in a straight line in sectional view but may extend in a curved line or in an uneven shape. The side surface 74 is positioned on a region in which the electricity receiving portion 50a overlaps with the upper insulating layer 63 in plan view. Specifically, the side surface 74 is positioned on a flat portion 63a of the upper insulating layer 63. That is, the columnar shaped portion 71 covers the electricity receiving portion 50a and upper insulating layer 63. The side surface 74 is positioned on the flat portion 63a, by which the columnar shaped portion 71 can be stably formed as compared with a case where the side surface 74 is positioned on the first end portion 63b, the thickness of which varies to a relatively large extent.

The wide portion 72 is one example of the second conductive layer provided at an upper end of the columnar shaped portion 71. The wide portion 72 is a portion in which the upper end of the columnar shaped portion 71 is enlarged on an xy plane. The size and the shape of the wide portion 72 in plan view are in agreement with the size and the shape of the gate pad 70 in plan view. In plan view, the wide portion 72 is larger than the columnar shaped portion 71. In plan view, the columnar shaped portion 71 is positioned inside the wide portion 72.

In plan view, an outline of the wide portion 72 is formed from an outline of the columnar shaped portion 71 to a peripheral edge side of the semiconductor layer 10, with a certain interval kept. In plan view, the wide portion 72 (the gate pad 70) overlaps with a part of the active region 3 and the non-active region 4. That is, in plan view, the wide portion 72 (the gate pad 70) overlaps with the trench gate structure 21 and the trench source structure 31.

The wide portion 72 has an upper surface 73 which is used in electrically connecting the semiconductor device 1 (the vertical type transistor 2) with another circuit. In this preferred embodiment, the upper surface 73 of the wide portion 72 is formed in an island shape in plan view and connected to a power supply circuit for supplying a gate voltage. That is, in this preferred embodiment, the gate pad 70 is different from the main surface gate electrode 50 and not formed in a line. For example, a metal wire is connected to the upper surface 73 of the wide portion 72 by wire bonding. The metal wire includes, for example, at least one type of metal such as aluminum, copper and gold. In this preferred embodiment, an aluminum wire is connected to the gate pad (the upper surface 73 of the wide portion 72) by wedge bonding.

In order to conduct wire bonding appropriately, the wide portion 72 is required to have at least a certain size. A planar shape of the wide portion 72 is, for example, square. In this case, a size of the wide portion 72 may be, for example, not less than 800 μm×800 μm and not more than 1 mm×1 mm. In this case, a metal wire can be connected to the wide portion 72 in any given direction. As a matter of course, the size of the wide portion 72 may be larger than 1 mm×1 mm. Further, the planar shape of the wide portion 72 may be rectangular. In this case, the size of the wide portion 72 may be not less than 400 mm×800 mm.

In plan view, an area of the wide portion 72 (that is, an area of the gate pad 70) is larger than an area of the electricity receiving portion 50a of the main surface gate electrode 50. In other words, in plan view, a connecting area of a connecting portion of the gate pad 70 with the main surface gate electrode 50 is less than an area of the upper surface 73 of the gate pad 70. The area of the wide portion 72 is not less than 200 times and not more than 40000 times larger than the area of the electricity receiving portion 50a. The area of the wide portion 72 may be not less than 400 times larger than the area of the electricity receiving portion 50a. As an example, the area of the wide portion 72 may be about 2500 times larger than the area of the electricity receiving portion 50a.

The columnar shaped portion 71 includes a metal material such as copper or a copper alloy in which copper is a main component. The wide portion 72 includes a metal material such as copper or a copper alloy in which copper is a main component. The wide portion 72 may be formed, for example, with the same conductive material as the columnar shaped portion 71. The wide portion 72 may be formed with a conductive material different from that of the columnar shaped portion 71.

A height of the gate pad 70 (a length in the z axis direction) is a sum of the height of the columnar shaped portion 71 (a length in the z axis direction) and a thickness of the wide portion 72 (a length in the z axis direction). The height of the gate pad 70 is, for example, in excess of 0 mm and not more than 1 mm (for example, not less than several dozens of μm and not more than several hundreds of μm). As shown in FIG. 2, the height of the columnar shaped portion 71 is larger (longer) than the thickness of the wide portion 72. The height of the columnar shaped portion 71 may be not more than the thickness of the wide portion 72.

The source pad 75 overlaps with the main surface source electrode 55 in plan view and is electrically connected to the main surface source electrode 55. The source pad 75 is provided on the main surface source electrode 55. The source pad 75 extends in a thick plate shape in a normal direction (in the z axis direction) of the upper surface 56 of the main surface source electrode 55. In plan view, an area of the source pad 75 is smaller than an area of the main surface source electrode 55.

The source pad 75 covers the upper surface 56 of the main surface source electrode 55. In addition, the source pad 75 covers a part of the flat portion 63a of the upper insulating layer 63 and the second end portion 63c. Further, the source pad 75 covers a part of the flat portion 65a of the end insulating layer 65 and the end portion 65b. The thickness of the source pad 75 (a length in the z axis direction) is larger (longer) than the thickness of each of the upper insulating layer 63 and the end insulating layer 65 (a length in the z axis direction).

Specifically, the thickness of the source pad 75 is larger (longer) than a maximum thickness of the portion of the upper insulating layer 63 on the main surface source electrode 55 and a maximum thickness of the portion of the end insulating layer 65 on the main surface source electrode 55. Thereby, the top of the source pad 75 becomes higher than the top of the upper insulating layer 63 and the top of the end insulating layer 65.

The source pad 75 has a side surface 77 which extends vertically or substantially vertically. The side surface 77 is not necessarily required to extend in a straight line in sectional view but may extend in a curved line or in an uneven shape. The side surface 77 is positioned in a region in which the main surface source electrode 55 overlaps with the upper insulating layer 63 in plan view or in a region in which the main surface source electrode 55 overlaps with the end insulating layer 65 in plan view.

Specifically, the side surface 77 is positioned on the flat portion 63a of the upper insulating layer 63 or on the flat portion 65a of the end insulating layer 65. That is, the source pad 75 is in contact with the main surface source electrode 55 and the upper insulating layer 63, or the main surface source electrode 55 and the end insulating layer 65. In this preferred embodiment, the source pad 75 is in contact with the main surface source electrode 55, the upper insulating layer 63 and the end insulating layer 65. Thereby, as with a case of the columnar shaped portion 71, the source pad 75 can be stably formed.

The source pad 75 has an upper surface 76 which is used in electrically connecting the semiconductor device 1 (the vertical type transistor 2) with other circuits. In this preferred embodiment, a power supply circuit for supplying a source voltage is connected to the upper surface 76 of the source pad 75. For example, a metal wire is connected to the upper surface 76 of the source pad 75 by wire bonding. The metal wire includes, for example, at least one type of metal such as aluminum, copper and gold. In this preferred embodiment, an aluminum wire is connected to the source pad 75 by wedge bonding.

The source pad 75 is provided with an interval kept from the gate pad 70 in plan view. It is, thereby, possible to prevent a short circuit caused by contact between the source pad 75 and the gate pad 70. The source pad 75 is formed with a conductive material. Specifically, the source pad 75 includes a metal material such as copper or a copper alloy in which copper is a main component. The source pad 75 is, for example, formed with the same material as the gate pad 70. In this case, the source pad 75 can be formed in the same step as the gate pad 70. The source pad 75 may be formed with a material different from that of the gate pad 70.

The source pad 75 has an area which is not less than 50% of an area of the semiconductor layer 10 (the first main surface 11) in plan view. Preferably, the source pad 75 has an area which is not less than 70% of an area of the semiconductor layer 10 (the first main surface 11) in plan view. On the other hand, the gate pad 70 has an area which is not more than 20% of the area of the semiconductor layer 10 (the first main surface 11) in plan view. Preferably, the gate pad 70 has an area which is not more than 10% of the area of the semiconductor layer 10 (the first main surface 11) in plan view.

The source pad 75 is arranged in a region which includes a central position of the semiconductor layer 10 (the first main surface 11) in plan view. The gate pad 70 is arranged in a region away from the source pad 75. The gate pad 70 may be arranged in a region which includes the central position of the semiconductor layer 10 (the first main surface 11). In this case, the source pad 75 may be arranged such as to surround a periphery of the gate pad 70.

The semiconductor device 1 includes a mold layer 80 which is added between the source pad 75 and the gate pad 70. Specifically, the mold layer 80 fills a space between the gate pad 70 and the source pad 75. Further, the mold layer 80 covers the upper insulating layer 63 and the end insulating layer 65. Still further, the mold layer 80 is provided annularly along an outer periphery of the semiconductor layer 10 (a peripheral edge of the first main surface 11) in plan view.

The mold layer 80 is formed with an insulating material. The mold layer 80 may include a thermosetting resin. The mold layer 80 includes, for example, an epoxy resin. The mold layer 80 may include, for example, an epoxy resin which includes carbon and glass fiber, etc. A thickness of the mold layer 80 (a length in the z axis direction) is, for example, in excess of 0 mm and not more than 1 mm (for example, not less than several dozens of μm and not more than several hundreds of μm). The thickness of the mold layer 80 may be larger than the thickness of the semiconductor layer 10.

In this preferred embodiment, the mold layer 80 has an upper surface 81 which is formed such as to be flush with the upper surface 73 of the gate pad 70 and the upper surface 76 of the source pad 75. That is, no step is formed at a boundary portion with each of the upper surface 73 of the gate pad 70, the upper surface 76 of the source pad 75 and the upper surface 81 of the mold layer 80. In this case, the upper surface 73 of the gate pad 70 may be constituted of a ground surface. The upper surface 76 of the source pad 75 may also be constituted of a ground surface. The upper surface 81 of the mold layer 80 may also be constituted of a ground surface. That is, the upper surface 81 of the mold layer 80 may form a single ground surface together with the upper surface 73 of the gate pad 70 and the upper surface 76 of the source pad 75.

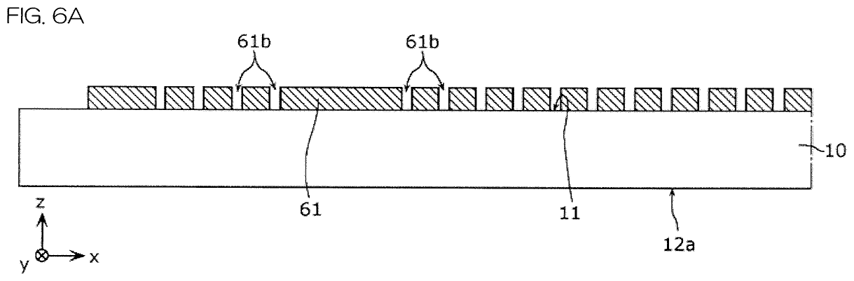

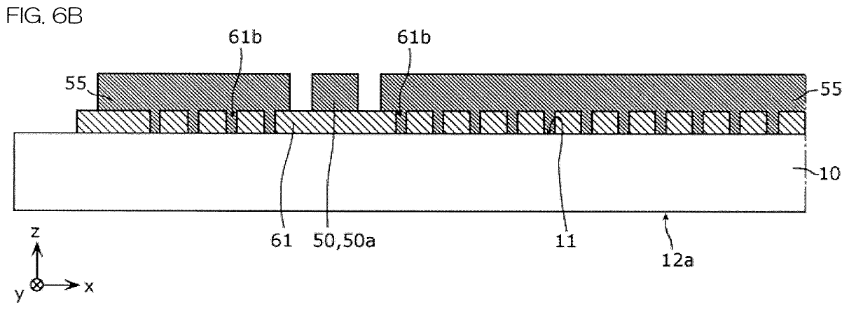

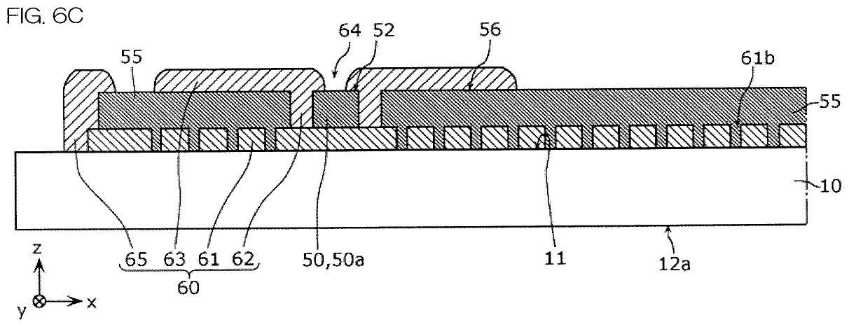

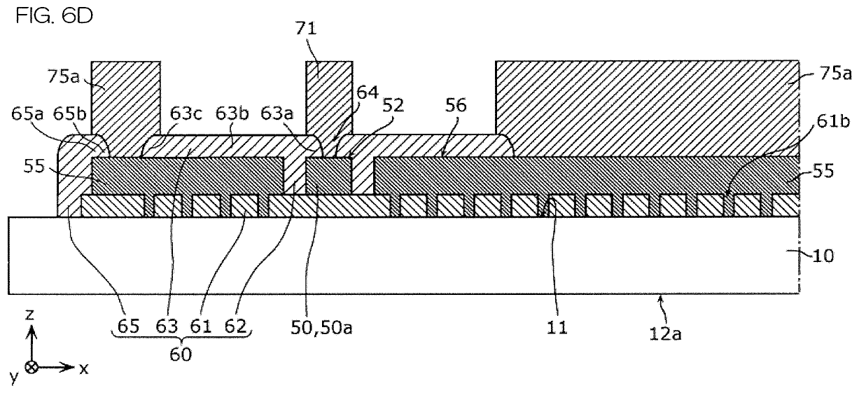

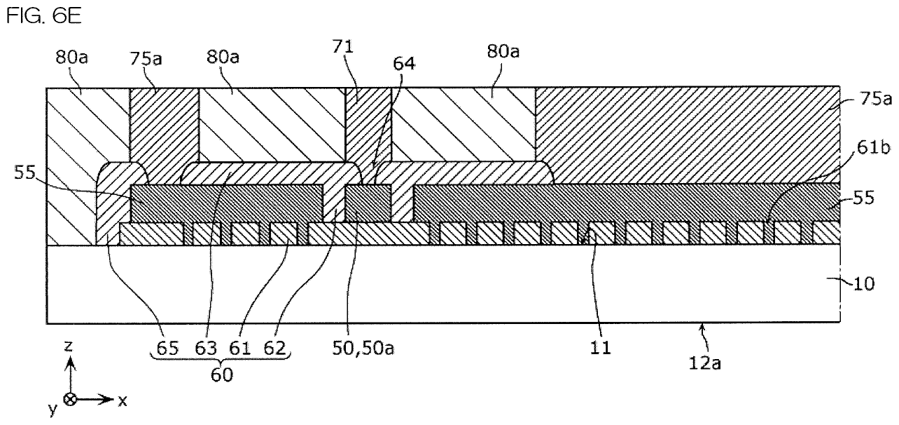

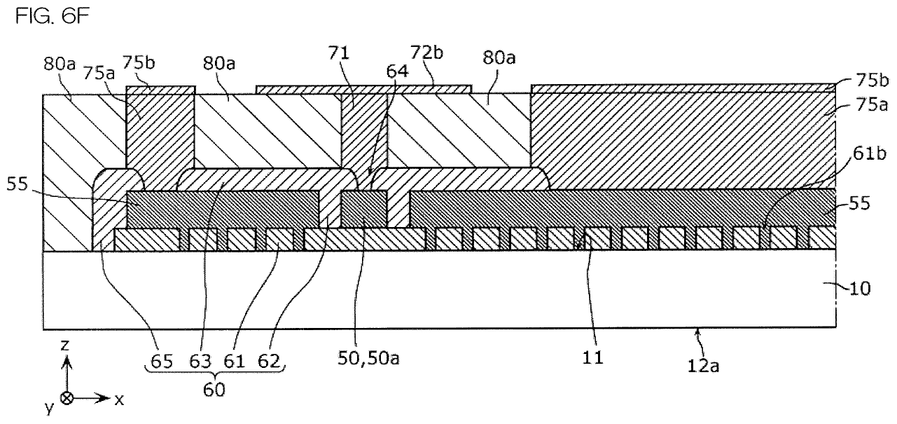

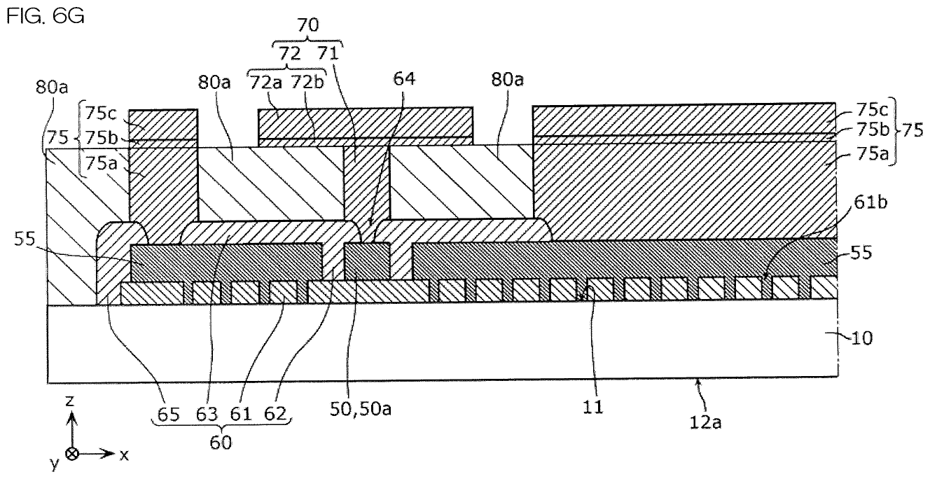

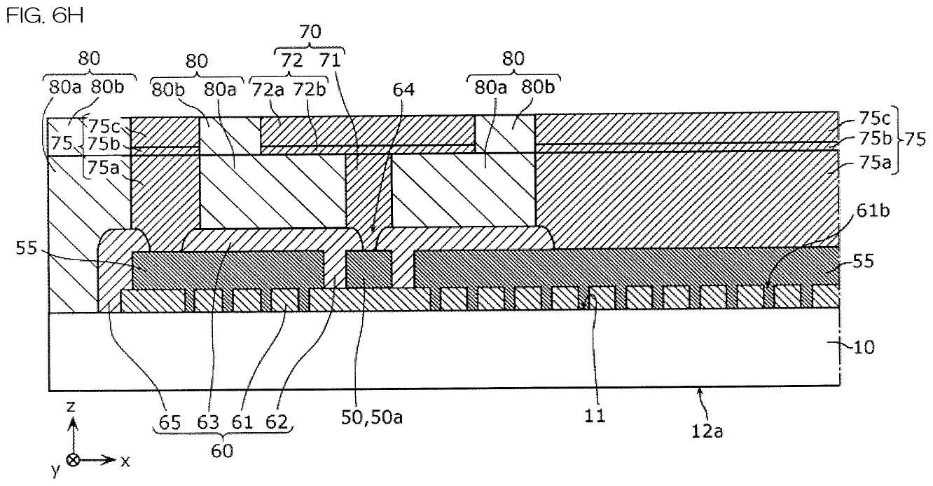

Hereinafter, a description will be given of a method for manufacturing the semiconductor device 1 according to the first preferred embodiment. FIG. 6A to FIG. 6G are each a sectional view which shows one step of the method for manufacturing the semiconductor device shown in FIG. 1. Hereinafter, a description will be given, with an emphasis placed on a method for manufacturing an upper configuration of the semiconductor layer 10 in particular. A known method can be applied to a method for forming the trench gate structure 21, the trench source structure 31 and each well region (each semiconductor region) on the semiconductor layer 10.

First, as shown in FIG. 6A, the lower insulating layer 61 is formed on the first main surface 11 of the semiconductor layer 10 (a semiconductor wafer). The lower insulating layer 61 has a plurality of source contact holes 61b. For example, in this step, first, plasma CVD (Chemical Vapor Deposition) is used to form an insulating film which includes silicon oxide, etc. Next, a part of the insulating film after film formation is removed by a photolithography method and an etching method. Thereby, formed is the lower insulating layer 61 having the plurality of source contact holes 61b.

Next, the main surface gate electrode 50 and the main surface source electrode 55 are formed as shown in FIG. 6B. In this step, first, for example, a metal film is formed on the entire first main surface 11 such as to cover the lower insulating layer 61 by a vapor deposition method or a sputtering method. Next, a part of the metal film after film formation is removed by a photolithography method and an etching method. Thereby, the metal film is patterned to form the main surface gate electrode 50 and the main surface source electrode 55. The main surface gate electrode 50 and the main surface source electrode 55 may be formed in a different step by repeating a metal film forming step which uses a different material and a pattering step of the metal film.

Next, the side insulating layer 62, the upper insulating layer 63 and the end insulating layer 65 are formed as shown in FIG. 6C. The upper insulating layer 63 has the through hole 64. This step includes, for example, a coating step and an exposure/development step. In the coating step, a liquid-type photosensitive resin material which is a source of each insulating layer is coated by a spin coating method on the upper surface 52 of the main surface gate electrode 50 and the upper surface 56 of the main surface source electrode 55. In the exposure/development step, a photosensitive resin material is cured by exposure and, thereafter, an unnecessary portion of the photosensitive resin material is removed by an ashing method or a wet etching method. Thereby, the side insulating layer 62, the upper insulating layer 63 and the end insulating layer 65 are formed.

Next, as shown in FIG. 6D, the columnar shaped portion 71 is formed on the electricity receiving portion 50a of the main surface gate electrode 50, and a lower source pad 75a is formed on the main surface source electrode 55. In this step, for example, a metal plating layer is selectively formed by an electroplating method or an electroless plating method at least partially on a portion of the main surface gate electrode 50 which is not covered by the upper insulating layer 63 and at least partially on a portion of the main surface source electrode 55 which is not covered by the upper insulating layer 63.

A part of the metal plating layer is formed on the flat portion 63a as well, the first end portion 63b and the second end portion 63c of the upper insulating layer 63. The part of the metal plating layer is formed on the flat portion 65a and the end portion 65b of the end insulating layer 65 as well. Regarding the metal plating layer, a portion which is positioned on the electricity receiving portion 50a of the main surface gate electrode 50 and a portion which is positioned on the flat portion 63a and the first end portion 63b of the upper insulating layer 63 are formed as the columnar shaped portion 71 which is a part of the gate pad 70. With regard to the metal plating layer, a portion which is positioned on the main surface source electrode 55 and a portion which is positioned on the second end portion 63c of the upper insulating layer 63 and the end insulating layer 65 are formed as the lower source pad 75a which is a part of the source pad 75.

Next, a lower mold layer 80a is formed as shown in FIG. 6E. This step includes, for example, a film forming step, a curing step and a thinning step. In the film forming step, a liquid-type resin material (for example, an epoxy resin which is one example of a thermosetting resin) which is a source of the lower mold layer 80a is coated or printed on the entire first main surface 11 of the semiconductor layer 10. In this step, the resin material covers the entire columnar shaped portion 71 and the lower source pad 75a. In addition, the resin material enters into a space between the columnar shaped portion 71 and the lower source pad 75a.

In the curing step, the resin material which has been coated or printed is cured by heating. In the thinning step, the resin material is ground until the columnar shaped portion 71 and the lower source pad 75a are exposed. Thereby, as shown in FIG. 6E, the upper surface of the columnar shaped portion 71, the upper surface of the lower mold layer 80a and the upper surface of the lower source pad 75a are formed such as to be flush with each other.

Next, a gate wiring layer 72b and a source wiring layer 75b are formed as shown in FIG. 6F. The gate wiring layer 72b and the source wiring layer 75b are each formed, for example, with the same material as the columnar shaped portion 71 and the lower source pad 75a. The gate wiring layer 72b has the same size and the same shape as the wide portion 72 of the gate pad 70 in plan view. The source wiring layer 75b has the same size and the same shape as the lower source pad 75a in plan view. The gate wiring layer 72b and the source wiring layer 75b function as a seed wiring which is a starting point of film formation in a subsequent plating step.

Next, as shown in FIG. 6G, a wide portion 72a of the gate pad 70 is formed on the gate wiring layer 72b, and an upper source pad 75c of the source pad 75 is formed on the source wiring layer 75b. In this step, for example, an electroplating method or an electroless plating method is used to form a metal plating layer selectively only on the upper surface of the gate wiring layer 72b and the upper surface of the source wiring layer 75b.

Next, as shown in FIG. 6H, an upper mold layer 80b is formed. This step includes, for example, a film forming step, a curing step and a thinning step. In the film forming step, the entire wide portion 72a and the entire upper source pad 75c are covered with a resin material (for example, an epoxy resin as one example of a thermosetting resin), for example, by coating or printing.

In the curing step, a resin material which has been coated or printed is cured by heating. In the thinning step, the resin material is ground until the wide portion 72a and the upper source pad 75c are exposed. Thereby, the upper surface of the wide portion 72a, the upper surface of the upper mold layer 80b and the upper surface of the upper source pad 75c are formed such as to be flush, as shown in FIG. 6H.

Thereby, as shown in FIG. 6H, the wide portion 72 of the gate pad 70 is formed by the gate wiring layer 72b and the wide portion 72a. Further, the source pad 75 is formed by the lower source pad 75a, the source wiring layer 75b and the upper source pad 75c. Still further, the mold layer 80 is constituted of the lower mold layer 80a and the upper mold layer 80b.

As described so far, the gate pad 70 and the source pad 75 are formed by a two-step plating. In FIG. 2, etc., which has been described above, illustration or description of the gate pad 70, the source pad 75, or the mold layer 80 for a specific layer structure is omitted. A description of the specific layer structure of the gate pad 70, the source pad 75 and the mold layer 80 will be also applied to FIG. 2, etc., which has been described above.

Next, the semiconductor layer 10 is thinned by grinding the second main surface 12a of the semiconductor layer 10. Next, the drain electrode 40 is formed on the second main surface 12 by a vapor evaporation method or a sputtering method. Thereafter, the semiconductor layer 10, etc., is cut selectively together with the mold layer 80 to manufacture the semiconductor device 1 shown in FIG. 2.

The method for manufacturing the semiconductor device 1 is only an example and shall not be restricted to the method described above. For example, the gate pad 70 and the source pad 75 may be formed by a film forming method other than a plating method.

As described so far, the semiconductor device 1 according to the first preferred embodiment is a semiconductor device which includes the vertical type transistor 2. The semiconductor device 1 includes the semiconductor layer 10, the vertical type transistor 2, the gate electrode 20, the source electrode 30, the drain electrode 40, the main surface gate electrode 50, the main surface source electrode 55 and the gate pad 70.

The semiconductor layer 10 has the first main surface 11 and the second main surface 12 on the other side of the first main surface 11 and includes SiC as a main component. The vertical type transistor 2 is provided on the first main surface 11. The gate electrode 20 is provided on the first main surface 11 as a gate electrode of the vertical type transistor 2. The source electrode 30 is provided on the first main surface 11 as a source electrode of the vertical type transistor 2, with an interval kept from the gate electrode 20.

The drain electrode 40 is provided on the second main surface 12 as a drain electrode of the vertical type transistor 2. The main surface gate electrode 50 covers a part of the first main surface 11. The main surface source electrode 55 is provided with an interval kept from the main surface gate electrode 50 in plan view. The gate pad 70 overlaps with the main surface gate electrode 50 in plan view and is electrically connected to the main surface gate electrode 50. The main surface gate electrode 50 is smaller than the gate pad 70 in plan view. For example, the main surface gate electrode 50 is electrically connected to the gate electrode 20. The main surface source electrode 55 is electrically connected to the source electrode 30.

On the assumption that the main surface gate electrode 50 is used as an electrode pad for wire bonding in place of the gate pad 70, it is necessary that the main surface gate electrode 50 is formed such as to be equal in size to the wide portion 72 of the gate pad 70. In this case, a region of the semiconductor layer 10 which is covered by the main surface gate electrode 50 is formed as the non-active region 4.

Therefore, the size of the non-active region 4 becomes the size of the main surface gate electrode 50 which is formed equal in size to the wide portion 72, and, consequently, the active region 3 becomes small. That is, the size of the non-active region 4 is much larger than the size of the non-active region 4 of the semiconductor device 1 according to this preferred embodiment. Consequently, the active region 3 becomes small and the semiconductor layer 10 is not effectively used to result in a difficulty of reduction in size and cost.

In contrast thereto, in the semiconductor device 1 according to this preferred embodiment, the gate pad 70 (the wide portion 72) which is connected to the main surface gate electrode 50 is provided, and wire bonding is given to the gate pad 70 (the wide portion 72). It is, therefore, possible to secure the gate pad 70 having a sufficient size for conducting wire bonding appropriately, while making small the main surface gate electrode 50. Thereby, due to reduction in size of the main surface gate electrode 50, a region which is not covered by the main surface gate electrode 50 can be expanded and used as the active region 3. Then, the semiconductor device 1 capable of securing a wide actuation region is realized.

For example, the gate pad 70 overlaps with a part of the main surface source electrode 55 in plan view. Thereby, a region directly under the wide portion 72 can be used as the active region 3. Further, the main surface source electrode 55 provided directly under the wide portion 72 of the gate pad 70 is able to easily secure an electrical connecting portion to the plurality of source electrodes 30.

Hereinafter, a second preferred embodiment will be described. The second preferred embodiment is mainly different from the first preferred embodiment in that a semiconductor device further includes a current detecting electrode and an electrode pad connected to the current detecting electrode and the current detecting electrode is smaller than the electrode pad. Hereinafter, a description will be made, with an emphasis given to a difference from the first preferred embodiment, and a common description will be omitted or simplified.

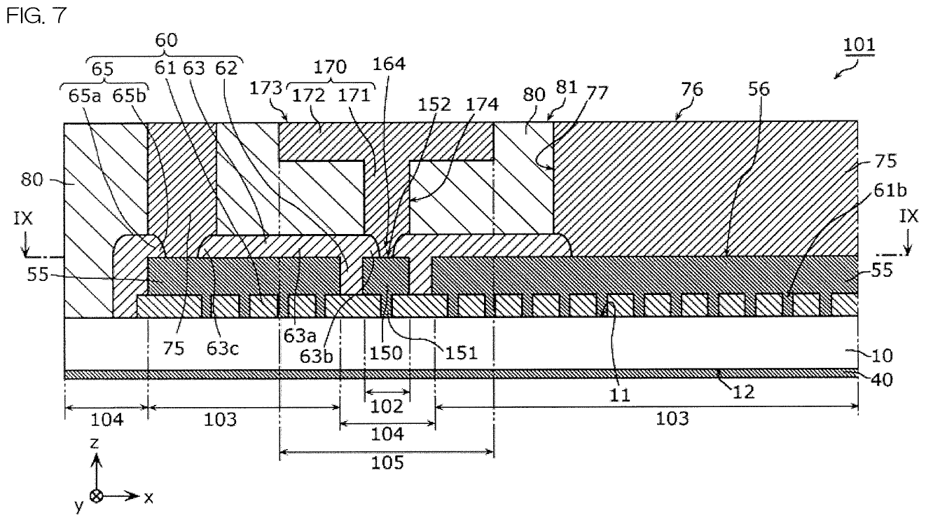

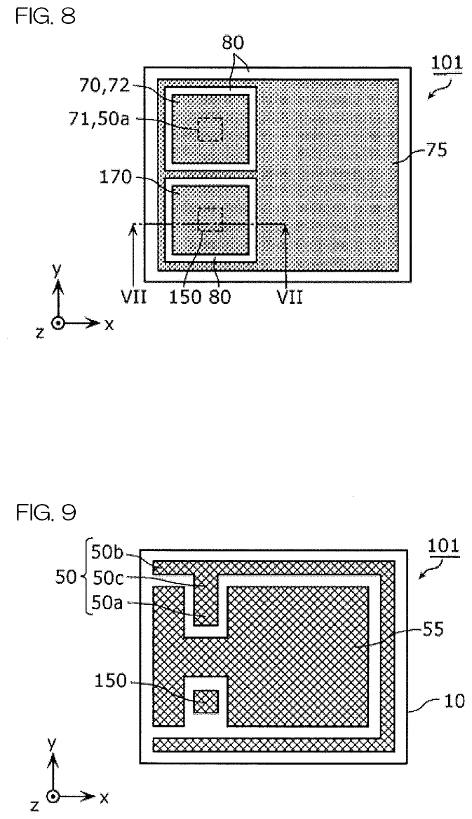

FIG. 7 is a sectional view of a semiconductor device 101 according to the second preferred embodiment. FIG. 8 is a plan view of the semiconductor device 101 shown in FIG. 7. FIG. 9 is a plan view of an electrode upper surface of the semiconductor device 101 taken along line IX-IX in FIG. 7. Specifically, FIG. 7 shows a cross section along line VII-VII in FIG. 8. Specifically, FIG. 9 is a plan view when the semiconductor device 101 is viewed from the positive side of the z axis through a gate pad 70, a source pad 75, a current detecting pad 170 and a mold layer 80 shown in FIG. 8. Although not shown in FIG. 7, the semiconductor device 101 includes a vertical type transistor 2 which allows a current to flow in a thickness direction of a semiconductor layer 10, as with a case of the first preferred embodiment.

As shown in FIG. 7 to FIG. 9, the semiconductor device 101 includes a main surface gate electrode 50, a main surface source electrode 55 and a current detecting electrode 150. The main surface gate electrode 50 and the main surface source electrode 55 according to the second preferred embodiment are each different in position and shape, as compared with a case of the first preferred embodiment. However, their configurations are substantially the same as the case of the first preferred embodiment. Therefore, a description of the main surface gate electrode 50 and the main surface source electrode 55 according to the second preferred embodiment will be omitted.

The current detecting electrode 150 is one example of a third electrode. The current detecting electrode 150 is arranged, with an interval kept from the main surface gate electrode 50 and the main surface source electrode 55 in plan view. In this preferred embodiment, the current detecting electrode 150 is arranged in a region demarcated by the main surface gate electrode 50 and the main surface source electrode 55 in plan view. The current detecting electrode 150 corresponds to a portion in which a part of the main surface source electrode 55 according to the first preferred embodiment is separated.

The current detecting electrode 150 includes, for example, at least one type of metal such as conductive polysilicon, titanium, nickel, copper, aluminum, silver, gold and tungsten or metal nitrides such as titanium nitride. The current detecting electrode 150 is formed, for example, with the same material as the main surface gate electrode 50 and the main surface source electrode 55.

Of a plurality of source electrodes 30 provided on a first main surface 11 of the semiconductor layer 10, the current detecting electrode 150 is electrically connected to N number of source electrodes 30. N is a natural number. N is, for example, not more than 10. The vertical type transistor 2 included in the semiconductor device 101 allows a drain current to flow to the plurality of source electrodes 30 provided on the first main surface 11 of the semiconductor layer 10 from a drain electrode 40 provided on a second main surface 12 of the semiconductor layer 10. The current detecting electrode 150 is an electrode for taking out a current (one component of the drain current) which flows through the N number of source electrodes 30, of the plurality of source electrodes 30. The N number of source electrodes 30 are used in detecting a current (a drain current) flowing through the vertical type transistor 2.

As shown in FIG. 7, the current detecting electrode 150 is provided on a lower insulating layer 61. The current detecting electrode 150 is electrically connected to one or more source electrodes 30 through one or more source contact holes 61b provided on the lower insulating layer 61. For example, the number of source contact holes 61b corresponds to N. That is, the number of source contact holes 61b is adjusted, thus making it possible to adjust the N number of source electrodes 30 to which the current detecting electrode 150 is connected.

The main surface source electrode 55 is electrically connected to M number of source electrodes 30, of the plurality of source electrodes 30. M is a natural number larger than N. M is, for example, not less than 100 times or 10000 times larger than N. Therefore, a current which is not less than 1/10000 and not more than 1/100 smaller than a current flowing through the main surface source electrode 55 flows through the current detecting electrode 150 which is connected to the N number of source electrodes 30.

Thereby, even in a case where a large drain current flows between the drain electrode 40 of the semiconductor device 101 and the plurality of source electrodes 30 due to some reason, it is possible to decrease a current which flows through the current detecting electrode 150. For example, a maximum magnitude of the current flowing through the current detecting electrode 150 can be suppressed to about 1 A. Thereby, an increase in current can be detected within a current detection range by using the current detecting electrode 150. In other words, an increase or a decrease in drain current can be indirectly detected within a detection range of the current detecting electrode 150.

The current detecting electrode 150 is smaller than the current detecting pad 170 in plan view. A planar shape of the current detecting electrode 150 is, for example, square or rectangular. A length of one side of the current detecting electrode 150 is not less than 5 μm and not more than 50 μm. As one example, the current detecting electrode 150 may have a square planar shape and have a size of about 20 μm×20 μm. As shown in FIG. 9, the size of the current detecting electrode 150 is equal to a size of an electricity receiving portion 50a of the main surface gate electrode 50. The size of the current detecting electrode 150 may be smaller than the size of the electricity receiving portion 50a. The size of the current detecting electrode 150 may be larger than the size of the electricity receiving portion 50a.

The current detecting electrode 150 has an area which is not more than 20% of an area of the semiconductor layer 10 (the first main surface 11) in plan view. Preferably, the current detecting electrode 150 has an area which is not more than 10% of the area of the semiconductor layer 10 (the first main surface 11). The current detecting electrode 150 is arranged in a region away from the main surface source electrode 55 and the main surface gate electrode 50 in plan view. The current detecting electrode 150 may be arranged in a region which includes a central position of the semiconductor layer 10. In this case, the main surface source electrode 55 may be arranged such as to surround a periphery of the current detecting electrode 150.

As shown in FIG. 7 and FIG. 8, the semiconductor device 101 includes the gate pad 70, the source pad 75 and the current detecting pad 170. The gate pad 70 and the source pad 75 according to the second preferred embodiment are each different in position and shape, as compared with a case of the first preferred embodiment. However, their configurations are substantially the same as the case of the first preferred embodiment. Therefore, a description of the gate pad 70 and the source pad 75 according to the second preferred embodiment will be omitted.

The current detecting pad 170 is one example of a second electrode pad. The current detecting pad 170 overlaps with the current detecting electrode 150 in plan view and is electrically connected to the current detecting electrode 150. In the semiconductor device 101 according to this preferred embodiment, the current detecting pad 170 connected to the current detecting electrode 150 has the same configuration as the gate pad 70.

Specifically, as shown in FIG. 7, the current detecting pad 170 includes a columnar shaped portion 171 and a wide portion 172. The columnar shaped portion 171 is one example of a first conductive layer provided on the current detecting electrode 150. The columnar shaped portion 171 extends in a columnar shape in a normal direction (the z axis direction) of an upper surface 152 of the current detecting electrode 150. The columnar shaped portion 171 is connected to the current detecting electrode 150 through a through hole 164 provided on an upper insulating layer 63.

The columnar shaped portion 171 covers the upper surface 152 of the current detecting electrode 150. Further, the columnar shaped portion 171 covers a part of a flat portion 63a of the upper insulating layer 63 and a first end portion 63b thereof. A height of the columnar shaped portion 171 (a length in the z axis direction) is larger (longer) than a thickness of the upper insulating layer 63 (a length in the z axis direction). Specifically, the height of the columnar shaped portion 171 is larger (longer) than a maximum thickness of a portion of the upper insulating layer 63 positioned on the current detecting electrode 150. Thereby, the top of the columnar shaped portion 171 becomes higher than the top of the upper insulating layer 63.

The columnar shaped portion 171 has a side surface 174 which extends vertically or substantially vertically. The side surface 174 is not necessarily required to extend in a straight line in sectional view but may extend in a curved line or in an uneven shape. The side surface 174 is positioned at a region in which the current detecting electrode 150 overlaps with the upper insulating layer 63 in plan view. Specifically, the side surface 174 is positioned on the flat portion 63a of the upper insulating layer 63. That is, the columnar shaped portion 171 covers the current detecting electrode 150 and the upper insulating layer 63. It is, thereby, possible to stably form the columnar shaped portion 171, as with the columnar shaped portion 71 according to the first preferred embodiment.

The wide portion 172 is one example of a second conductive layer provided at an upper end of the columnar shaped portion 171. The wide portion 172 is a portion in which the upper end of the columnar shaped portion 171 is enlarged on an xy plane. The size and the shape of the wide portion 172 in plan view are in agreement with the size and the shape of the current detecting pad 170 in plan view. The wide portion 172 has an upper surface 173 which is used in electrically connecting the semiconductor device 101 (the vertical type transistor 2) with other circuits.

In this preferred embodiment, the upper surface 173 of the wide portion 172 is connected to a control circuit for controlling the semiconductor device 101 (the vertical type transistor 2) based on a detected current. For example, a metal wire is connected to the upper surface 173 of the wide portion 172 by wire bonding. The metal wire includes, for example, at least one type of metal such as aluminum, copper and gold. In this preferred embodiment, an aluminum wire is connected to the current detecting pad 170 (the upper surface 173 of the wide portion 172) by wedge bonding.

In order to conduct wire bonding appropriately, the wide portion 172 is required to have at least a certain size. A planar shape of the wide portion 172 is, for example, square. In this case, the size of the wide portion 172 may be not less than 800 μm×800 μm and not more than 1 mm×1 mm. In this case, the metal wire can be connected to the wide portion 172 in any given direction. The size of the wide portion 172 may be larger than 1 mm×1 mm.

The planar shape of the wide portion 172 may be rectangular. In this case, the size of the wide portion 172 may be not less than 400 mm×800 mm. The size of the wide portion 172 is the same as the size of the wide portion 72 of the gate pad 70. The size of the wide portion 172 may be smaller than the size of the wide portion 72. The size of the wide portion 172 may be larger than the size of the wide portion 72.

In plan view, an area of the wide portion 172 (that is, an area of the current detecting pad 170) is larger than an area of the current detecting electrode 150. The area of the wide portion 172 is not less than 200 times and not more than 40000 times larger than the area of the current detecting electrode 150. The area of the wide portion 172 may be not less than 400 times larger than the area of the current detecting electrode 150. As one example, the area of the wide portion 172 may be about 2500 times larger than the area of the current detecting electrode 150.

The columnar shaped portion 171 includes a metal material such as copper or a copper alloy in which copper is a main component. The wide portion 172 includes a metal material such as copper or a copper alloy in which copper is a main component. The wide portion 172 is formed, for example, with the same conductive material as the columnar shaped portion 171. The wide portion 172 may be formed with a conductive material different from that of the columnar shaped portion 171. The current detecting pad 170 is, for example, formed with the same material as the gate pad 70 and the source pad 75. Thereby, it is possible to form the current detecting pad 170, the gate pad 70 and the source pad 75 in the same step.

A height of the current detecting pad 170 (a length in the z axis direction) is a sum of the height of the columnar shaped portion 171 (a length in the z axis direction) and a thickness of the wide portion 172 (a length in the z axis direction). The height of the current detecting pad 170 is, for example, in excess of 0 mm and not more than 1 mm (for example, not less than several dozens of μm and not more than several hundreds of μm). As shown in FIG. 7, the height of the columnar shaped portion 171 is larger (longer) than the thickness of the wide portion 172. The height of the columnar shaped portion 171 may be not more than the thickness of the wide portion 172.

The current detecting pad 170 has an area which is not more than 20% of an area of the semiconductor layer 10 (the first main surface 11) in plan view. Preferably, the current detecting pad 170 has an area which is not more than 10% of the area of the semiconductor layer 10 (the first main surface 11) in plan view. Further, the current detecting pad 170 is arranged in a region away from the gate pad 70 and the source pad 75. The current detecting pad 170 may be arranged in a region which includes a central position of the semiconductor layer 10 (the first main surface 11). In this case, the source pad 75 may be arranged such as to surround a periphery of the current detecting pad 170.

In this preferred embodiment, as shown in FIG. 7, the semiconductor device 101 includes an active region 103 and a non-active region 104. The active region 103 is a main region through which a drain current of the vertical type transistor 2 flows. The active region 103 is a region which overlaps with the main surface source electrode 55 in plan view. The active region 103 is free of a region which overlaps with one of the main surface gate electrode 50 and the current detecting electrode 150. On the other hand, a part of a region which overlaps with the gate pad 70 and the current detecting pad 170 in plan view is included in the active region 103.

The non-active region 104 is a region which will not actuate as the vertical type transistor 2. The non-active region 104 is a region other than the active region 103 in plan view. As shown in FIG. 7, a current detecting region 102 is included in the non-active region 104. The current detecting region 102 is a region which overlaps with the current detecting electrode 150 in plan view. In this preferred embodiment, a region which overlaps with the main surface gate electrode 50 or the current detecting electrode 150 in plan view is included in the non-active region 104.

Specifically, the current detecting pad 170 overlaps with a part of the main surface source electrode 55 in plan view. That is, the part of the main surface source electrode 55 is positioned directly under the current detecting pad 170. In this preferred embodiment, the main surface source electrode 55 is drawn out to a region which overlaps with the current detecting pad 170 in plan view and, therefore, a part of the region in which the current detecting pad 170 overlaps with the main surface source electrode 55 can be used as the active region 103. Thereby, it is possible to secure a larger area of the active region 103, while securing an area of the current detecting pad 170.

As described so far, the semiconductor device 101 according to the second preferred embodiment further includes the plurality of source electrodes 30, the current detecting electrode 150 and the current detecting pad 170. The plurality of source electrodes 30 are arranged, with an interval kept from each other, in plan view. The current detecting electrode 150 is provided with an interval kept from the main surface gate electrode 50 and the main surface source electrode 55 in plan view and electrically connected to the N number (N is a natural number) of the source electrodes 30. The current detecting pad 170 overlaps with the current detecting electrode 150 in plan view and is electrically connected to the current detecting electrode 150. The main surface source electrode 55 is electrically connected to the M number (M is a natural number larger than N) of the source electrodes 30. The current detecting electrode 150 is smaller than the current detecting pad 170 in plan view.

As described above, the N number of source electrodes 30 (that is, the source electrodes 30 included in the current detecting region 102) to which the current detecting electrode 150 is connected may be, for example, not more than 10. In contrast thereto, as shown in FIG. 7, the number of source electrode 30 included in a range 105 directly under the wide portion 172 of the current detecting pad 170 is much larger than 10.

Therefore, on the assumption that the current detecting electrode 150 is used as an electrode pad for wire bonding in place of the current detecting pad 170, the current detecting electrode 150 is required to be formed equal in size to the wide portion 172 of the current detecting pad 170. In this case, the range 105 directly under the wide portion 172 of the current detecting pad 170 is formed as the non-active region 104.

Therefore, the size of the non-active region 104 becomes the size of the current detecting electrode 150 which is formed such as to be equal in size to the wide portion 172, and the active region 103 becomes small. That is, the size of the non-active region 104 is much larger than the size of the non-active region 104 of the semiconductor device 101 according to this preferred embodiment. Therefore, the active region 103 becomes small and the semiconductor layer 10 is not effectively used, thus resulting in a difficulty of reduction in size and cost.

In contrast thereto, according to the semiconductor device 101 of this preferred embodiment, the current detecting pad 170 (the wide portion 172) connected to the current detecting electrode 150 is provided and wire bonding is given to the current detecting pad 170 (the wide portion 172). Therefore, it is possible to secure the current detecting pad 170 having a sufficient size for conducting wire bonding appropriately, while making small the current detecting electrode 150. Further, the current detecting electrode 150 becomes small and, therefore, a region which is not covered by the current detecting electrode 150 can be expanded and used as the active region 103. Thereby, the semiconductor device 101 which secures a wide actuation region is provided.

A method for manufacturing the semiconductor device 101 according to this preferred embodiment is the same as the method for manufacturing the semiconductor device 1 according to the first preferred embodiment. Specifically, in a patterning step of each of the main surface gate electrode 50, the main surface source electrode 55 and the current detecting electrode 150, in a patterning step of the insulating layer 60 and in a patterning step of each of the gate pad 70, the source pad 75 and the current detecting pad 170, the shapes thereof are individually adjusted, thus making it possible to manufacture the semiconductor device 101.

In the semiconductor device 101 according to this preferred embodiment, a description has been given of an example in which the gate pad 70 has the same configuration as the current detecting pad 170. However, the gate pad 70 may have the same configuration as the source pad 75.

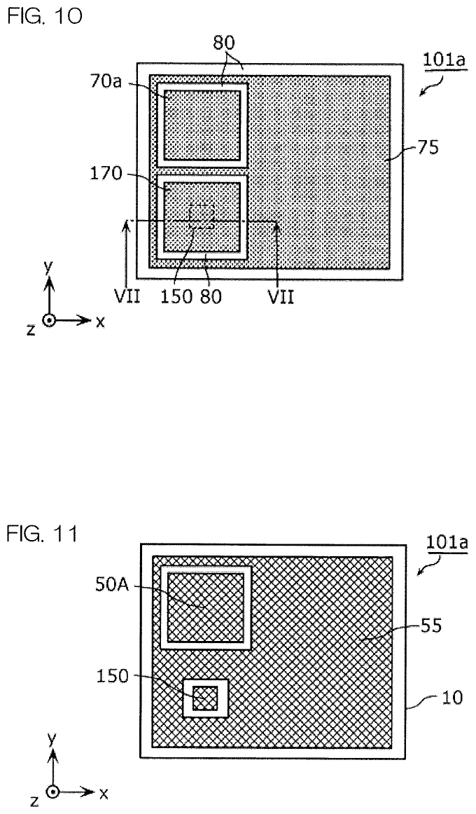

FIG. 10 is a plan view of a modified example of the semiconductor device 101 according to the second preferred embodiment (hereinafter, referred to as a semiconductor device 101a). FIG. 11 is a plan view of an electrode upper surface of the semiconductor device 101a shown in FIG. 10. FIG. 10 and FIG. 11 respectively correspond to FIG. 8 and FIG. 9 of the second preferred embodiment.

In the semiconductor device 101a according to the modified example, a main surface gate electrode 50A and a gate pad 70a have the same size and the same shape in plan view. That is, in plan view, the main surface gate electrode 50A is larger than the electricity receiving portion 50a of the main surface gate electrode 50 according to the second preferred embodiment. A current detecting electrode 150 and a current detecting pad 170 are the same as those of the second preferred embodiment. That is, the semiconductor device 101a according to the modified example includes the current detecting electrode 150 as one example of a first electrode and the current detecting pad 170 as one example of a first electrode pad.

As described so far, in the semiconductor device 101a according to the modified example, a configuration which is large in area in plan view (specifically, the current detecting pad 170) is applied only to the current detecting electrode 150. It is, thereby, possible to make the current detecting electrode 150 smaller than the current detecting pad 170, while securing an area of the pad electrically connected to the current detecting electrode 150. Therefore, a part of a region which overlaps with the current detecting pad 170 in plan view can be effectively used as an active region. Thereby, a wide actuation region can be secured.

Hereinafter, a description will be given of a third preferred embodiment. The third preferred embodiment is different mainly from the first preferred embodiment in that a semiconductor device further includes a diode having an electrode and an electrode pad connected to the electrode of the diode and the electrode of the diode is smaller than the electrode pad. Hereinafter, a description will be made, with an emphasis given to a difference from the first preferred embodiment, and a common description will be omitted or simplified.

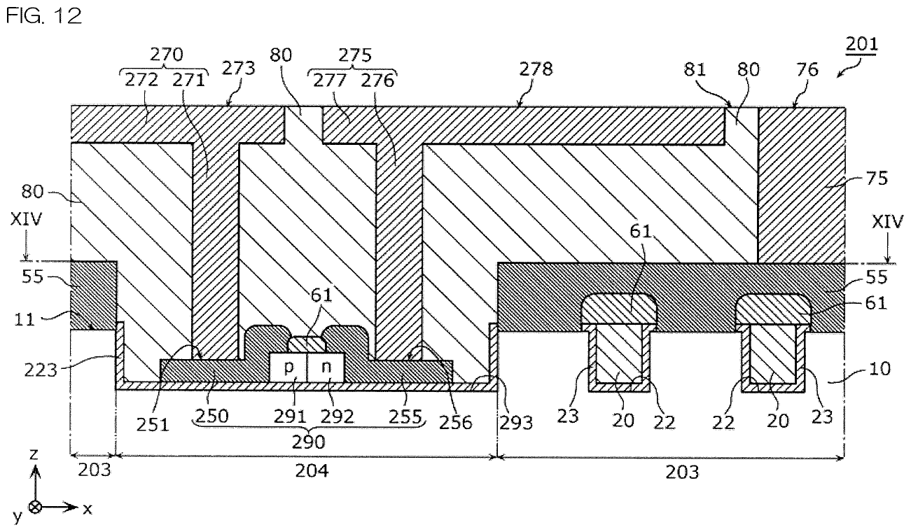

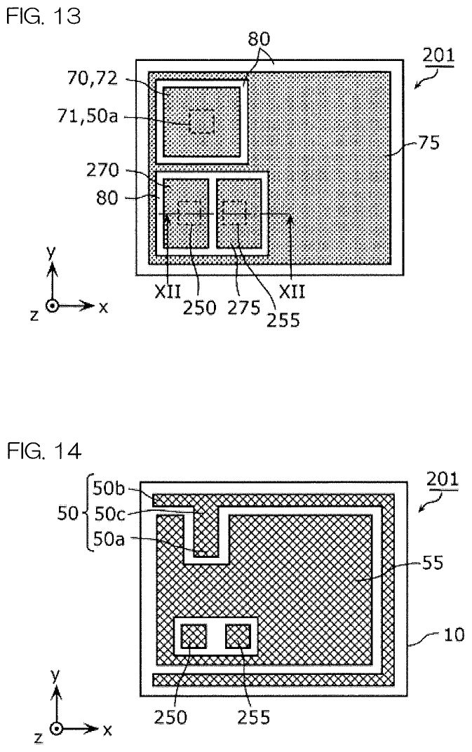

FIG. 12 is a sectional view which shows main parts of a semiconductor device 201 according to a third preferred embodiment. FIG. 13 is a plan view of the semiconductor device 201 shown in FIG. 12. FIG. 14 is a plan view taken along line XIV-XIV shown in FIG. 12. Specifically, FIG. 12 shows a cross section along line XII-XII in FIG. 13. Specifically, FIG. 14 is a plan view when the semiconductor device 201 is viewed from the positive side of the z axis through a gate pad 70, a source pad 75, an anode electrode pad 270, a cathode electrode pad 275 and a mold layer 80 shown in FIG. 13.

As shown in FIG. 12, the semiconductor device 201 includes a diode 290 provided on a first main surface 11 of a semiconductor layer 10. In this preferred embodiment, the diode 290 is a pn diode and includes a p-type semiconductor layer 291 and an n-type semiconductor layer 292. For example, the p-type semiconductor layer 291 includes polysilicon to which a p-type impurity is added, and the n-type semiconductor layer 292 includes polysilicon to which an n-type impurity is added. The p-type semiconductor layer 291 and the n-type semiconductor layer 292 are in contact with each other to constitute the pn diode having a pn junction.

The diode 290 is provided inside a recessed portion 293 provided on the first main surface 11 of the semiconductor layer 10. The recessed portion 293 is formed by digging the first main surface 11 of the semiconductor layer 10 toward a second main surface 12 side. For example, the recessed portion 293 has the same depth as that of the gate trench 22. The recessed portion 293 can be formed in the same step as the gate trench 22.

The recessed portion 293 has an area which is not more than 20% of an area of the semiconductor layer 10 (the first main surface 11) in plan view. Preferably, the recessed portion 293 has an area which is not more than 10% of the area of the semiconductor layer 10 (the first main surface 11) in plan view. The recessed portion 293 is provided in a region away from a main surface source electrode 55 and a main surface gate electrode 50 in plan view. The recessed portion 293 may be provided in a region which includes a central position of the semiconductor layer 10 (the first main surface 11). In this case, the main surface source electrode 55 may be arranged such as to surround a periphery of the recessed portion 293.

The semiconductor device 201 includes an insulating layer 223 which is formed such as to cover a bottom wall and a side wall of the recessed portion 293. The insulating layer 223 is interposed between the semiconductor layer 10 and the diode 290. That is, the diode 290 is provided on the insulating layer 223. The insulating layer 223 includes, for example, silicon oxide. The insulating layer 223 may include at least one type of impurity-free silicon, silicon nitride, aluminum oxide, aluminum nitride and aluminum oxynitride. The insulating layer 223 includes, for example, the same material as the gate insulating layer 23 and has the same thickness as the gate insulating layer 23. Thereby, the insulating layer 223 can be formed in the same step as the gate insulating layer 23.

The semiconductor layer 10 may not be provided with either or both of the recessed portion 293 and the insulating layer 223. The diode 290 may be provided on the first main surface 11 of the semiconductor layer 10. In this case, the diode 290 may be arranged on the insulating layer 223 which covers the first main surface 11.

The diode 290 includes an anode electrode 250 and a cathode electrode 255. It is possible to detect a temperature of the semiconductor device 201 by a magnitude of voltage between the anode electrode 250 and the cathode electrode 255. That is, the diode 290 is used as a temperature sensor (temperature sensitive diode).

The anode electrode 250 is electrically connected to the p-type semiconductor layer 291. The anode electrode 250 includes, for example, at least one type of metal such as conductive polysilicon, titanium, nickel, copper, aluminum, silver, gold and tungsten or metal nitrides such as titanium nitride.

The cathode electrode 255 is electrically connected to the n-type semiconductor layer 292. As shown in FIG. 14, the cathode electrode 255 is provided with an interval kept from the anode electrode 250 in plan view. In this preferred embodiment, a lower insulating layer 61 is provided between the cathode electrode 255 and the anode electrode 250. Further, the anode electrode 250 and the cathode electrode 255 are provided with an interval kept from each of the main surface gate electrode 50 and the main surface source electrode 55 in plan view.

As shown in FIG. 14, the main surface gate electrode 50 and the main surface source electrode 55 according to the third preferred embodiment are each different in disposition and shape, as compared with those of the first preferred embodiment. However, their configurations are substantially the same as those of the first preferred embodiment. Therefore, a description of the main surface gate electrode 50 and the main surface source electrode 55 according to the third preferred embodiment will be omitted.

The cathode electrode 255 includes, for example, at least one type of metal such as conductive polysilicon, titanium, nickel, copper, aluminum, silver, gold and tungsten or metal nitrides such as titanium nitride. The cathode electrode 255 may be formed with the same material as the anode electrode 250.

As shown in FIG. 12 and FIG. 13, the semiconductor device 201 includes the gate pad 70, the source pad 75, the anode electrode pad 270 and the cathode electrode pad 275. The gate pad 70 and the source pad 75 according to the third preferred embodiment are each different in disposition and shape, as compared with those of the first preferred embodiment. However, their configurations are substantially the same as those of the first preferred embodiment. Therefore, a description of the gate pad 70 and the source pad 75 according to the third preferred embodiment will be omitted.

The anode electrode pad 270 overlaps with the anode electrode 250 in plan view and is electrically connected to the anode electrode 250. In the semiconductor device 201 according to this preferred embodiment, the anode electrode pad 270 connected to the anode electrode 250 has the same configuration as the gate pad 70.

Specifically, as shown in FIG. 12, the anode electrode pad 270 includes a columnar shaped portion 271 and a wide portion 272. The columnar shaped portion 271 is one example of a first conductive layer provided on the anode electrode 250. The columnar shaped portion 271 extends in a columnar shape in a normal direction (the z axis direction) of an upper surface 251 of the anode electrode 250.

The wide portion 272 is one example of a second conductive layer provided at an upper end of the columnar shaped portion 271. The wide portion 272 is a portion in which the upper end of the columnar shaped portion 271 is enlarged on an xy plane. The size and the shape of the wide portion 272 in plan view are in agreement with the size and the shape of the anode electrode pad 270 in plan view. The wide portion 272 has an upper surface 273 which is used in electrically connecting the semiconductor device 201 (the diode 290) to other circuits.

In this preferred embodiment, the upper surface 273 of the wide portion 272 is connected to a voltmeter or the like for detecting a voltage of the anode electrode 250 and that of the cathode electrode 255. A metal wire is, for example, connected to the upper surface 273 of the wide portion 272 by wire bonding. The metal wire includes, for example, at least one type of metal such as aluminum, copper and gold. In this preferred embodiment, an aluminum wire is connected to the anode electrode pad 270 (the upper surface 273 of the wide portion 272) by wedge bonding.

In order to conduct wire bonding appropriately, the wide portion 272 is required to have at least a certain size. The shape and the size of the wide portion 272 in plan view are, for example, the same as the shape and the size of the wide portion 72 of the gate pad 70 in plan view. At least one of the shape and the size of the wide portion 272 in plan view may be different from the shape and the size of the wide portion 72 in plan view.

In plan view, an area of the wide portion 272 (that is, an area of the anode electrode pad 270) is larger than an area of the anode electrode 250. The area of the wide portion 272 may be not less than 200 times and not more than 40000 times larger than the area of the anode electrode 250. The area of the wide portion 272 may be not less than 400 times larger than the area of the anode electrode 250. The area of the wide portion 272 may be, as one example, about 2500 times larger than the area of the anode electrode 250.

The columnar shaped portion 271 includes a metal material such as copper or a copper alloy in which copper is a main component. The wide portion 272 includes a metal material such as copper or a copper alloy in which copper is a main component. The wide portion 272 is formed, for example, with the same conductive material as the columnar shaped portion 271. The wide portion 272 may be formed with a conductive material different from that of the columnar shaped portion 271.

A height of the anode electrode pad 270 (a length in the z axis direction) is a sum of the height of the columnar shaped portion 271 (a length in the z axis direction) and a thickness of the wide portion 272 (a length in the z axis direction). The height of the anode electrode pad 270 is, for example, in excess of 0 mm and not more than 1 mm (for example, not less than several dozens of μm and not more than several hundreds of μm). As shown in FIG. 12, the height of the columnar shaped portion 271 is larger (longer) than the thickness of the wide portion 272. The height of the columnar shaped portion 271 may be not more than the thickness of the wide portion 272.

The cathode electrode pad 275 overlaps with the cathode electrode 255 in plan view and is electrically connected to the cathode electrode 255. In the semiconductor device 201 according to this preferred embodiment, the cathode electrode pad 275 connected to the cathode electrode 255 has the same configuration as the gate pad 70 and the anode electrode pad 270.

Specifically, as shown in FIG. 12, the cathode electrode pad 275 includes a columnar shaped portion 276 and a wide portion 277. The columnar shaped portion 276 is one example of a first conductive layer provided on the cathode electrode 255. The columnar shaped portion 276 extends in a columnar shape in a normal direction (the z axis direction) of an upper surface 256 of the cathode electrode 255.

The wide portion 277 is one example of a second conductive layer provided at an upper end of the columnar shaped portion 276. The wide portion 277 is a portion in which the upper end of the columnar shaped portion 276 is enlarged on an xy plane. The size and the shape of the wide portion 277 in plan view are in agreement with the size and the shape of the cathode electrode pad 275 in plan view.

The wide portion 277 has an upper surface 278 which is used in electrically connecting the semiconductor device 201 (the diode 290) to other circuits. In this preferred embodiment, the upper surface 278 of the wide portion 277 is connected to a voltmeter or the like for detecting a voltage of the anode electrode 250 and the cathode electrode 255. A metal wire is, for example, connected to the upper surface 278 of the wide portion 277 by wire bonding.

The columnar shaped portion 276 and the wide portion 277 of the cathode electrode pad 275 respectively have the same shape and the material as the columnar shaped portion 276 and the wide portion 277 of the anode electrode pad 270. Therefore, a description of the shape and the material of the cathode electrode pad 275 will be omitted.

The anode electrode pad 270 and the cathode electrode pad 275 are, for example, formed with the same material as the gate pad 70 and the source pad 75. Thereby, the anode electrode pad 270, the cathode electrode pad 275, the gate pad 70 and the source pad 75 can be formed in the same step.

The semiconductor device 201 may include an insulating layer (not shown) which covers a part of the upper surface 251 of the anode electrode 250 and a part of the upper surface 256 of the cathode electrode 255. The insulating layer is, for example, constituted of an organic material such as polyimide and PBO. In this case, a side surface of the columnar shaped portion 271 of the anode electrode pad 270 and a side surface of the columnar shaped portion 276 of the cathode electrode pad 275 may be each provided on a flat portion of the insulating layer, as with the side surface 74 of the columnar shaped portion 71 according to the first preferred embodiment.

The anode electrode pad 270 and the cathode electrode pad 275 each have an area which is not more than 20% of an area of the semiconductor layer 10 (the first main surface 11) in plan view. Preferably, the anode electrode pad 270 and the cathode electrode pad 275 have an area which is not more than 10% of the area of the semiconductor layer 10 (the first main surface 11) in plan view.

Further, the anode electrode pad 270 and the cathode electrode pad 275 are arranged in a region away from the gate pad 70 and the source pad 75. One of the anode electrode pad 270 and the cathode electrode pad 275 may be arranged in a region which includes a central position of the semiconductor layer 10 (the first main surface 11), and the source pad 75 may be arranged such as to surround peripheries of the anode electrode pad 270 and the cathode electrode pad 275.

In this preferred embodiment, as shown in FIG. 12, the semiconductor device 201 includes an active region 203 and a non-active region 204. The active region 203 is a main region through which a drain current of the vertical type transistor 2 flows. The active region 203 is a region which overlaps with the main surface source electrode 55 in plan view. A region which overlaps with one of the main surface gate electrode 50 and the recessed portion 293 is not included in the active region 203. A part of a region which overlaps with the gate pad 70, the anode electrode pad 270 and the cathode electrode pad 275 in plan view is included in the active region 103.

The non-active region 204 is a region which will not actuate as the vertical type transistor 2. The non-active region 204 is a region other than the active region 203 in plan view. As shown in FIG. 12, the diode 290 is formed in the non-active region 204. In this preferred embodiment, a region which overlaps with the main surface gate electrode 50 or the recessed portion 293 in plan view is included in the non-active region 204.

Specifically, the anode electrode pad 270 and the cathode electrode pad 275 each overlap with a part of the main surface source electrode 55 in plan view. That is, the part of the main surface source electrode 55 is positioned each directly under the anode electrode pad 270 and directly under the cathode electrode pad 275. In this preferred embodiment, the main surface source electrode 55 is drawn out to a region which overlaps with the anode electrode pad 270 or the cathode electrode pad 275 in plan view.

Therefore, a part of the region in which the main surface source electrode 55 overlaps with the anode electrode pad 270 or a part of the region in which the main surface source electrode 55 overlaps with the cathode electrode pad 275 can be used as the active region 203. Thereby, it is possible to secure a larger area of the active region 203, while securing areas of the anode electrode pad 270 and the cathode electrode pad 275.

As described so far, the semiconductor device 201 according to this preferred embodiment includes the diode 290, the anode electrode pad 270 and the cathode electrode pad 275. The diode 290 includes the anode electrode 250 and the cathode electrode 255 and is provided on the first main surface 11. The anode electrode pad 270 overlaps with the anode electrode 250 in plan view and is electrically connected to the anode electrode 250. The cathode electrode pad 275 overlaps with the cathode electrode 255 in plan view and is electrically connected to the cathode electrode 255. The anode electrode 250 is smaller than the anode electrode pad 270 in plan view. The cathode electrode 255 is smaller than the cathode electrode pad 275 in plan view.

On the assumption that the anode electrode 250 is used as an electrode pad for wire bonding in place of the anode electrode pad 270, the anode electrode 250 is required to have the same size as the wide portion 272. On the other hand, where the cathode electrode 255 is used as an electrode pad for wire bonding in place of the cathode electrode pad 275, the cathode electrode 255 is required to have the same size as the wide portion 277.

In the above-described cases, regions covered with the anode electrode 250 and the cathode electrode 255 are formed as the non-active region 204. Therefore, the size of the non-active region becomes the size of the anode electrode 250 and that of the cathode electrode 255 which are formed such as to be equal in size to the wide portion 272 and the wide portion 277, and the active region 203 becomes small. That is, the size of the non-active region is much larger than the size of the non-active region 204 of the semiconductor device 201 according to this preferred embodiment. Therefore, the semiconductor layer 10 is not effectively used to result in a difficulty of reduction in size and cost.

In contrast thereto, according to the semiconductor device 201 of this preferred embodiment, the anode electrode pad 270 (the wide portion 272) connected to the anode electrode 250 is provided, and the cathode electrode pad 275 (the wide portion 277) connected to the cathode electrode 255 is provided. Wire bonding is given to each of the anode electrode pad 270 (the wide portion 272) and the cathode electrode pad 275 (the wide portion 277).

Therefore, it is possible to secure the anode electrode pad 270 and the cathode electrode pad 275, each of which has a sufficient size for conducting wire bonding appropriately, while making small each of the anode electrode 250 and the cathode electrode 255. Further, each of the anode electrode 250 and the cathode electrode 255 becomes small and, therefore, a region which is not covered with the anode electrode 250 or the cathode electrode 255 can be expanded and used as the active region 203. The semiconductor device 201 capable of securing a large actuation region is provided, as described above.

The method for manufacturing the semiconductor device 201 according to this preferred embodiment is the same as the method for manufacturing the semiconductor device 1 according to the first preferred embodiment. Specifically, in a patterning step of each of the main surface gate electrode 50, the main surface source electrode 55, the anode electrode 250 and the cathode electrode 255, in a patterning step of the insulating layer 60 and in a patterning step of each of the gate pad 70, the source pad 75, the anode electrode pad 270 and the cathode electrode pad 275, their shapes are each adjusted, thus making it possible to manufacture the semiconductor device 201.

In the semiconductor device 201 according to this preferred embodiment, a description has been given of an example that the gate pad 70 has the same configuration as the anode electrode pad 270 and the cathode electrode pad 275. However, the gate pad 70 may have the same configuration as the source pad 75.

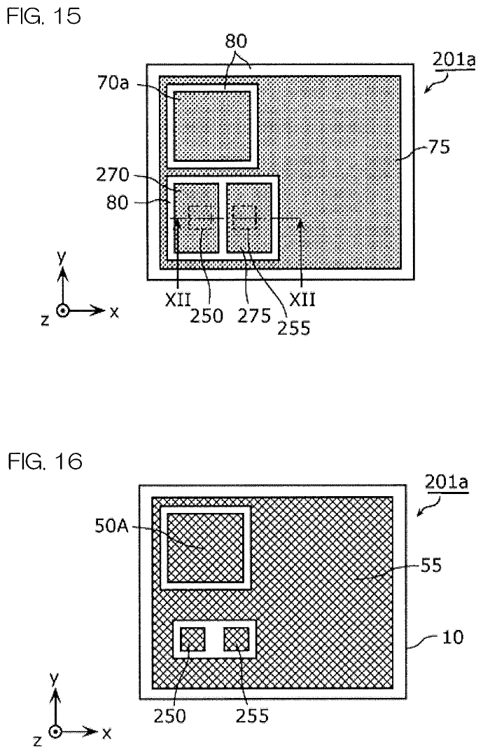

FIG. 15 is a plan view of a modified example of the semiconductor device 201 according to the third preferred embodiment (hereinafter, referred to as a semiconductor device 201a). FIG. 16 is a plan view which shows an electrode upper surface of the semiconductor device 201a shown in FIG. 15. FIG. 15 and FIG. 16 respectively correspond to FIG. 13 and FIG. 14 of the third preferred embodiment.

In the semiconductor device 201a according to the modified example, a main surface gate electrode 50A and a gate pad 70a have the same size and the same shape in plan view. That is, in plan view, the main surface gate electrode 50A is larger than the electricity receiving portion 50a of the main surface gate electrode 50 according to the third preferred embodiment.

An anode electrode 250, a cathode electrode 255, an anode electrode pad 270 and a cathode electrode pad 275 are the same as those of the third preferred embodiment. That is, the semiconductor device 201a according to the modified example includes the anode electrode 250 as one example of a first electrode and includes the anode electrode pad 270 as one example of a first electrode pad. The semiconductor device 201a according to the modified example includes the cathode electrode 255 as one example of a second electrode and includes the cathode electrode pad 275 as one example of a second electrode pad.

As described above, in the semiconductor device 201a according to the modified example, a configuration in which an area is enlarged in plan view (specifically, the anode electrode pad 270 and the cathode electrode pad 275) is applied only to the anode electrode 250 and the cathode electrode 255. That is, it is possible to make the anode electrode 250 smaller than the anode electrode pad 270 and to make the cathode electrode 255 smaller than the cathode electrode pad 275, while securing an area of the pad for electrically connecting each of the anode electrode 250 and the cathode electrode 255.

Thereby, a part of the region which overlaps with the anode electrode pad 270 or the cathode electrode pad 275 in plan view can be expanded as an active region and effectively used. Thus, it is possible to secure a wide actuation region.

Either one of the anode electrode pad 270 and the cathode electrode pad 275 may have the same configuration as the source pad 75. The anode electrode 250 and the anode electrode pad 270 may be, for example, equal in shape and size to each other in plan view. The cathode electrode 255 and the cathode electrode pad 275 may be equal in shape and size to each other in plan view.

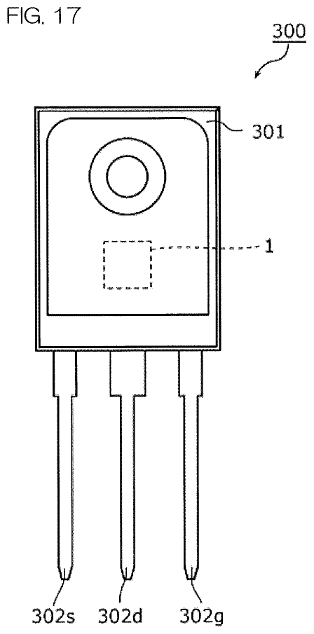

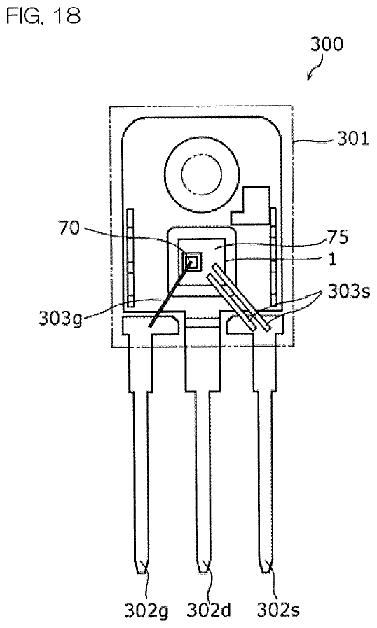

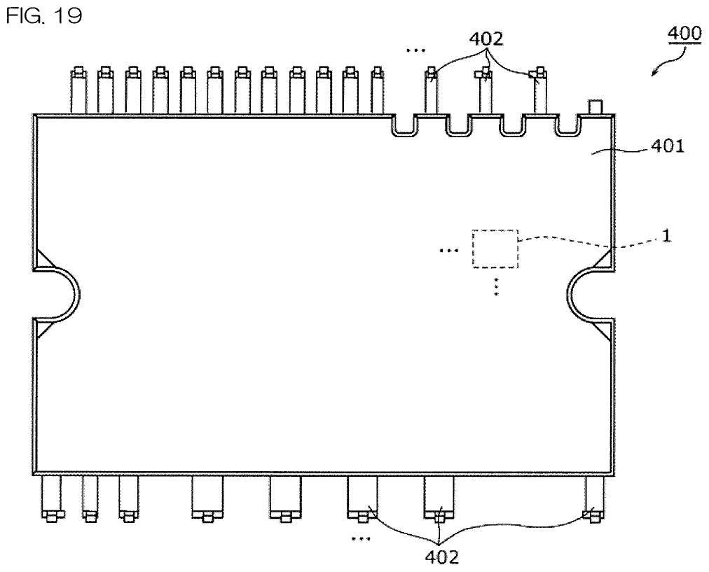

Hereinafter, a semiconductor package having a semiconductor device will be described as a fourth preferred embodiment. FIG. 17 is a rear view which shows one example of a semiconductor package 300 according to the fourth preferred embodiment. FIG. 18 is a front view which shows an inner structure of the semiconductor package 300 in FIG. 17.

As shown in FIG. 17 and FIG. 18, the semiconductor package 300 is what-is-called a TO (Transistor Outline) type semiconductor package. The semiconductor package 300 includes a package main body 301, a terminal 302d, a terminal 302g, a terminal 302s, a bonding wire 303g, a bonding wire 303s and a semiconductor device 1.

The package main body 301 is in a rectangular parallelepiped shape. The package main body 301 internally houses the semiconductor device 1. In other words, the package main body 301 is an encapsulant which encapsulates the semiconductor device 1. The package main body 301 may include an epoxy resin. The package main body 301 is formed, for example, with an epoxy resin which includes carbon, glass fiber, etc.

Each of the terminal 302d, the terminal 302g and the terminal 302s protrudes from a bottom portion of the package main body 301 and is arranged in a line along the bottom portion of the package main body 301. The terminal 302d, the terminal 302g and the terminal 302s are formed, for example, with aluminum but may be formed with other metal materials such as copper.

Inside the package main body 301, a gate pad 70 of the semiconductor device 1 is electrically connected to the terminal 302g by the bonding wire 303g, etc. A source pad 75 of the semiconductor device 1 is electrically connected to the terminal 302s by the bonding wire 303s, etc. A drain electrode 40 of the semiconductor device 1 is bonded to a wide portion of the terminal 302d positioned inside the package main body 301 by soldering or a sintered layer constituted of silver or copper.

The semiconductor package 300 may include the semiconductor device 101, 101a, 201 or 201a in place of the semiconductor device 1. In this case, the package main body 301 may further include a terminal to which the current detecting pad 170 of the semiconductor device 101 is connected. Further, the package main body 301 may also include a plurality of terminals to which the anode electrode pad 270 and the cathode electrode pad 275 of the semiconductor device 201 are each connected.

As described so far, the semiconductor package 300 includes the semiconductor device 1, 101, 101a, 201 or 201a, by which it is possible to secure a wider actuation region than a general semiconductor device.

Hereinafter, another example of the semiconductor package shown in FIG. 17 will be described. FIG. 19 is a front view of another example of the semiconductor package 300 according to the fourth preferred embodiment (hereinafter, referred to as a semiconductor package 400). The semiconductor package 400 shown in FIG. 19 is what-is-called a DIP (Dual In-line Package) type semiconductor package. The semiconductor package 400 includes a package main body 401, a plurality of terminals 402 and a semiconductor device 1.

The package main body 401 is in a rectangular parallelepiped shape. The package main body 401 internally houses the semiconductor device 1. In other words, the package main body 401 is an encapsulant which encapsulates the semiconductor device 1. The package main body 401 may include an epoxy resin. The package main body 401 is formed, for example, with an epoxy resin which includes carbon, glass fiber, etc.

The plurality of terminals 402 protrude from a long side of the package main body 401 and are arranged in a line along the long side of the package main body 401. The plurality of terminals 402 are formed, for example, with aluminum but may be formed with other metal materials such as copper.

Inside the package main body 401, a gate pad 70, a source pad 75 and a drain electrode 40 of the semiconductor device 1 are each electrically connected to a corresponding terminal 402 by a bonding wire or the like. The semiconductor package 400 may include the plurality of semiconductor devices 1. That is, the package main body 401 may internally house the plurality of semiconductor devices 1.

The semiconductor package 400 may be provided with the semiconductor device 101, 101a, 201 or 201a in place of the semiconductor device 1 or in addition to the semiconductor device 1. In this case, inside the package main body 401, the current detecting pad 170 of the semiconductor device 101 or the anode electrode pad 270 and the cathode electrode pad 275 of the semiconductor device 201 are each electrically connected to a corresponding terminal 402 by a bonding wire or the like.

As described so far, the semiconductor package 400 includes the semiconductor device 1, 101, 101a, 201 or 201a, by which it is possible to secure a wider actuation region than a general semiconductor device.

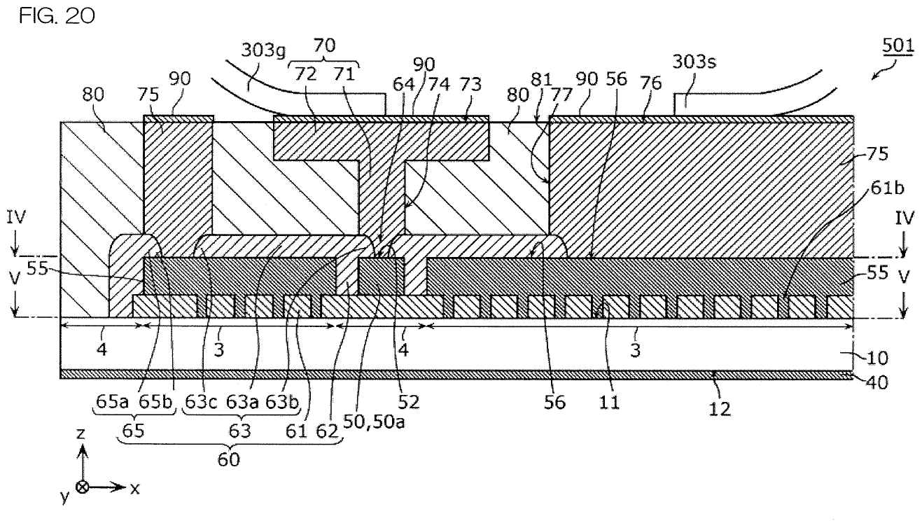

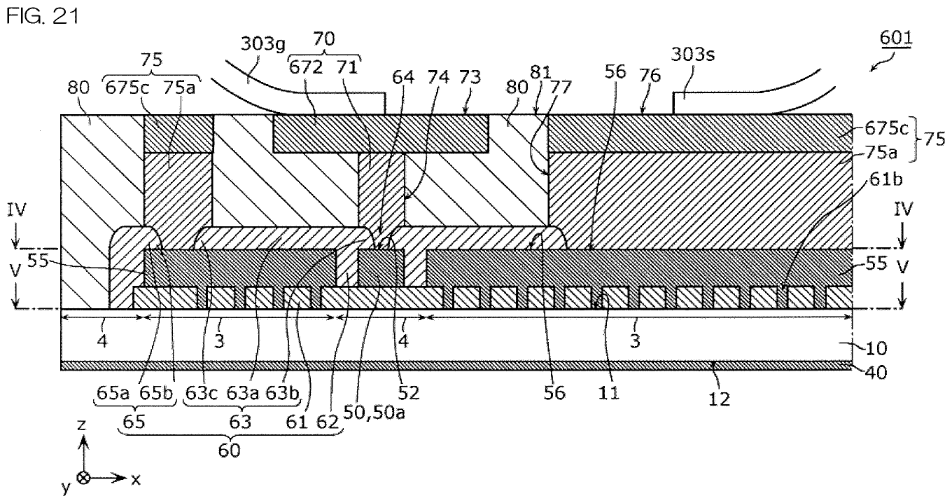

FIG. 20 is a sectional view which shows main parts of a semiconductor device 501 according to a first modified example of each of the above-described preferred embodiments. As described above, a bonding wire is used in electrically connecting a terminal of the semiconductor package 300 or 400 and the semiconductor device 1, 101, 101a, 201 or 201a. Where the bonding wire is a wire constituted of aluminum, as shown in FIG. 20, a nickel layer may be formed on each of an upper surface 73 of a gate pad 70 and an upper surface 76 of a source pad 75 each of which is a metal-plating layer.

FIG. 20 illustrates bonding wires 303g and 303s collectively as one example of the bonding wire. As shown in FIG. 20, a nickel layer 90 is one example of a metal layer which is formed with a metal material different from a metal material which forms the gate pad 70 and the source pad 75. The nickel layer 90 is a layer which includes nickel as a main component. Specifically, the nickel layer 90 is a metal layer which is solely constituted of nickel.

As with a case of the semiconductor device 101, 101a, 201 or 201a, the nickel layer 90 may be provided on each upper surface of the current detecting pad 170, the anode electrode pad 270 and the cathode electrode pad 275.

FIG. 21 is a sectional view which shows main parts of a semiconductor device 601 according to a second modified example of each of the above-described preferred embodiments. Like the semiconductor device 601 shown in FIG. 21, a gate pad 70 may include a columnar shaped portion 71 constituted of copper and a wide portion 672 constituted of nickel. A source pad 75 may include a lower source pad 75a constituted of copper and an upper source pad 675c constituted of nickel.

For example, the semiconductor device 601 shown in FIG. 21 can be manufactured by executing a plating method using nickel in place of copper in the plating step shown in FIG. 6G. In the example shown in FIG. 21, an upper surface 73 of the wide portion 672, an upper surface 76 of the upper source pad 675c and an upper surface 81 of a mold layer 80 are formed such as to be flush with each other.

In the example shown in FIG. 20 or FIG. 21, other layers may be formed in place of a nickel layer on a top surface of a metal plating layer which serves as a bonding portion of an aluminum-made bonding wire (specifically, the gate pad 70 and the source pad 75). For example, a two-layer structure which includes a nickel layer and a palladium layer provided on the nickel layer (that is, a NiPd layer) may be provided on the metal plating layer. Further, there may be formed a three-layer structure in which another metal layer such as a gold (Au) layer is formed on an upper surface of the two-layer structure (for example, an NiPdAu layer). The NiPd layer and the NiPdAu layer are preferably used not only in a case where a bonding wire is bonded but also in a case where an external terminal is bonded by silver sintering.

Preferred embodiments of the semiconductor package including the semiconductor device 1, 101, 101a, 201, 201a, 501 or 601 are not restricted to those of the semiconductor package 300 and the semiconductor package 400. As the semiconductor package, there may be adopted an SOP (Small Outline Package), a QFN (Quad Flat Non Lead Package), a DFP (Dual Flat Package), a QFP (Quad Flat Package), an SIP (Single Inline Package) or an SOJ (Small Outline J-leaded Package). There may also be adopted various types of similar semiconductor packages as the semiconductor package.

The semiconductor devices according to one or a plurality of modes have been so far described based on the plurality of preferred embodiments. The present invention shall not be, however, restricted to these preferred embodiments. A preferred embodiment in which various modifications conceivable by those skilled in the art are given to this preferred embodiment and a preferred embodiment which is constituted by a combination of constituents in a different preferred embodiment are also included in the scope of the present invention, unless deviating from the gist of the present invention.

For example, in plan view, the gate pad 70 may cover only a part of the main surface gate electrode 50. That is, the gate pad 70 may not completely cover the main surface gate electrode 50. A similar structure may be applied to each of the current detecting pad 170, the anode electrode pad 270 and the cathode electrode pad 275.

For example, in each of the preferred embodiments, a conductivity type of each of the semiconductor region and the semiconductor layer may be reversed. That is, in place of a p-type semiconductor, an n-type semiconductor may be provided, and in place of an n-type semiconductor, a p-type semiconductor may be provided.

For example, in each of the preferred embodiments, in place of an n⁺-type semiconductor substrate 13, a p⁺-type SiC semiconductor substrate may be used. Thereby, the vertical type transistor 2 is formed as an IGBT (Insulated Gate Bipolar Transistor). That is, there can be provided a semiconductor device which includes the IBGT as a vertical type transistor. In this case, a “source” of the MISFET is read as an “emitter” of the IGBT. Further, a “drain” of the MISFET is read as a “collector” of the IGBT. The emitter of the IGBT is one example of a first main electrode, and the collector of the IGBT is one example of a second main electrode. The semiconductor device according to each of the preferred embodiments is able to provide the same effects as those described above even in a case where it includes the IGBT in place of the MISFET.

Examples of features extracted from this description and drawings are indicated below. Although in the following, alphanumeric characters inside parentheses represent corresponding constituents in the preferred embodiments described above, this is not intended to restrict the scope of respective items to the preferred embodiments.

[A1] A method for manufacturing a semiconductor device (1, 101, 101a, 201, 201a) including a vertical type transistor (2), and the method for manufacturing the semiconductor device (1, 101, 101a, 201, 201a) including a first step in which, on a first main surface (11) of a semiconductor layer (10) that has the first main surface (11) and a second main surface (12) on the other side of the first main surface (11) and includes SiC as a main component, a control electrode (20) and a first main electrode (30) of the vertical type transistor (2) are formed, with an interval kept from each other, a second step in which a first electrode (50, 250) and a first electrode (55, 255) which cover a part of the first main surface (11) are formed, with an interval kept from each other, and a third step in which a first electrode pad (70) electrically connected to the first electrode (50, 250) is formed such as to overlap with the first electrode (50, 250) in plan view, in which the first electrode (50, 250) is smaller than the first electrode pad (70) in plan view.

[A2] The method for manufacturing the semiconductor device (1, 101, 101a, 201, 201a) according to A1, where the third step includes a fourth step for forming a first conductive layer (71) on the first electrode (50, 250), a fifth step for forming an insulating layer (80) along an outer periphery of the first conductive layer (71) in plan view, and a sixth step for forming a second conductive layer (72) larger than the first conductive layer (71) on the first conductive layer (71) and the insulating layer (80).

[A3] The method for manufacturing the semiconductor device (1, 101, 101a, 201, 201a) according to A2, where the sixth step includes a seventh step for forming a wiring layer (72b) larger than the first conductive layer (71) on the first conductive layer (71) and the insulating layer (80) and an eighth step for forming selectively a metal plating layer (72a) on the wiring layer (72b).

[A4] The method for manufacturing the semiconductor device (1, 101, 101a, 201, 201a) according to A2 or A3, where, in the fifth step, a resin material (80b) is molded such as to cover the first conductive layer (71) and the molded resin material (80b) is ground until the first conductive layer (71) is exposed to form the insulating layer (80).

[B1] A semiconductor device (1, 101, 101a, 201, 201a) including a vertical type transistor (2), and the semiconductor device (1, 101, 101a, 201, 201a) including a semiconductor layer (10) that has a first main surface (11) and a second main surface (12) on the other side of the first main surface (11) and includes SiC as a main component, a control electrode (20) of the vertical type transistor (2) which is provided on the first main surface (11), a first main electrode (30) of the vertical type transistor (2) which is provided on the first main surface (11), with an interval kept from the control electrode (20), a second main electrode (40) of the vertical type transistor (2) which is provided on the second main surface (12), a first electrode (50, 250) which covers a part of the first main surface (11), a first electrode (55, 255) which is provided with an interval kept from the first electrode (50, 250) in plan view, and a first electrode pad (70) which overlaps with the first electrode (50, 250) in plan view and is electrically connected to the first electrode (50, 250), in which the first electrode (50, 250) is smaller than the first electrode pad (70) in plan view.

[B2] The semiconductor device (1, 101, 101a, 201, 201a) according to B1, where the first electrode pad (70) overlaps with a part of the first electrode (55, 255) in plan view.

[B3] The semiconductor device (1, 101, 101a, 201, 201a) according to B1 or B2, where the first electrode (50, 250) is electrically connected to the control electrode (20) and the first electrode (55, 255) is electrically connected to the first main electrode (30).

[B4] The semiconductor device (1, 101, 101a, 201, 201a) according to B3, further including the plurality of first main electrodes (30) which are arranged, with an interval kept from each other in plan view, a third electrode (150) which is provided with an interval from the first electrode (50, 250) and the first electrode (55, 255) in plan view and electrically connected to N number (N is a natural number) of the first main electrodes (30), and a second electrode pad (170) which overlaps with the third electrode (150) in plan view and is electrically connected to the third electrode (150), in which the first electrode (55, 255) is electrically connected to M number (M is a natural number larger than N) of the first main electrodes (30) and the third electrode (150) is smaller than the second electrode pad (170) in plan view.

[B5] The semiconductor device (1, 101, 101a, 201, 201a) according to B3 or B4, including a diode (290) that further includes an anode electrode (250) and a cathode electrode (255) and is provided on the first main surface (11), an anode electrode pad (270) which overlaps with the anode electrode (250) in plan view and is electrically connected to the anode electrode (250), and a cathode electrode pad (275) which overlaps with the cathode electrode (255) in plan view and is electrically connected to the cathode electrode (255) in which the anode electrode (250) is smaller than the anode electrode pad (270) in plan view and the cathode electrode (255) is smaller than the cathode electrode pad (275) in plan view.

[B6] The semiconductor device (1, 101, 101a, 201, 201a) according to B1 or B2, including the plurality of first main electrodes (30) and in which the first electrode (50, 250) is electrically connected to one of the plurality of first main electrodes (30).

[B7] The semiconductor device (1, 101, 101a, 201, 201a) according to B1 or B2, further including a diode (290) provided on the first main surface (11) and a second electrode pad which overlaps with the first electrode (55, 255) in plan view and is electrically connected to the first electrode (55, 255) in which the first electrode (50, 250) is an anode electrode (250) of the diode (290), and the first electrode (55, 255) is a cathode electrode (255) of the diode (290) and smaller than the second electrode pad (170) in plan view.

[C1] A semiconductor device (1, 101, 101a, 201, 201a), including a semiconductor layer (10) that has a main surface (11) and includes SiC as a main component, a gate structure (21) which is formed in the main surface (11), an insulating layer (61) which is formed on the main surface (11) such as to cover the gate structure (21), a gate main electrode (50) which is arranged on the insulating layer (61) and electrically connected to the gate structure (21), and a gate pad electrode (70) which includes a connecting portion arranged on the gate main electrode (50) such as to be connected to the gate main electrode (50) and connected to the gate main electrode (50) with a first area in plan view and an electrode surface (73) having a second area exceeding the first area in plan view.

[C2] The semiconductor device (1, 101, 101a, 201, 201a) according to C1, where the electrode surface (73) of the gate pad electrode (70) is exposed to the outside.

[C3] The semiconductor device (1, 101, 101a, 201, 201a) according to C1 or C2, where the gate main electrode (50) is formed in a line on the insulating layer (61).

[C4] The semiconductor device (1, 101, 101a, 201, 201a) according to any one of C1 to C3, where the second area of the electrode surface (73) exceeds an area of the gate main electrode (50).

[C5] The semiconductor device (1, 101, 101a, 201, 201a) according to any one of C1 to C4, further including an active region (3, 103, 203) provided on the semiconductor layer (10) and a non-active region (4, 104, 204) provided in a region outside the active region (3, 103, 203) on the semiconductor layer (10), in which the gate structure (21) is formed in the active region (3, 103, 203), the gate main electrode (50) is formed in the non-active region (4, 104, 204) in plan view, and the gate pad electrode (70) overlaps with the active region (3, 103, 203) and the non-active region (4, 104, 204) in plan view.

[C6] The semiconductor device (1, 101, 101a, 201, 201a) according to any one of C1 to C5, further including a current conductive electrode (55) which is arranged on the insulating layer (61), with an interval kept from the gate main electrode (50).

[C7] The semiconductor device (1, 101, 101a, 201, 201a) according to C6, where the gate pad electrode (70) overlaps with a part of the current conductive electrode (55) in plan view.

[C8] The semiconductor device (1, 101, 101a, 201, 201a) according to C6 or C7, further including a current conductive pad electrode (75) arranged on the current conductive electrode (55).

[C9] The semiconductor device (1, 101, 101a, 201, 201a) according to C8, where the current conductive pad electrode (75) overlaps with a part of the gate main electrode (50) in plan view.

[C10] The semiconductor device (1, 101, 101a, 201, 201a) according to C8 or C9, where the current conductive pad electrode (75) includes an electrode surface (76) which has a third area exceeding the second area of the gate pad electrode (70) in plan view.

[C11] The semiconductor device (1, 101, 101a, 201, 201a) according to any one of C1 to C10, further including a first resin layer (63, 65) for partially covering the gate main electrode (50) such as to expose a part of the gate main electrode (50) on the insulating layer (61), in which the gate pad electrode (70) is arranged on a portion of the gate main electrode (50) which is exposed from the first resin layer (63, 65).

[C12] The semiconductor device (1, 101, 101a, 201, 201a) according to C11, further including a second resin layer (80) for partially covering the first resin layer (63, 65) such as to expose a part of the gate main electrode (50) on the insulating layer (61), in which the gate pad electrode (70) is arranged on a portion of the gate main electrode (50) which is exposed from the first resin layer (63, 65) and the second resin layer (80).

[C13] The semiconductor device (1, 101, 101a, 201, 201a) according to C12, where the first resin layer (63, 65) is constituted of a photosensitive resin layer and the second resin layer (80) is constituted of a thermosetting resin layer.

[C14] The semiconductor device (1, 101, 101a, 201, 201a) according to any one of C1 to C13, where the gate structure (21) is constituted of a trench gate structure (21).

[C15] A semiconductor device (1, 101, 101a, 201, 201a) including a semiconductor layer (10) which has a main surface (11), an active region (3, 103, 203) which is provided on the semiconductor layer (10), a non-active region (4, 104, 204) which is provided in a region of the semiconductor layer (10) outside the active region (3, 103, 203), a plurality of gate structures (21) which are formed in the active region (3, 103, 203), an insulating layer (61) which is formed on the main surface (11) such as to cover the plurality of gate structures (21), a gate main electrode (50) which is arranged on the insulating layer (61) such as to be electrically connected to the plurality of gate structures (21) and overlaps with the non-active region (4, 104, 204) in plan view, and a gate pad electrode (70) which is arranged on the gate main electrode (50) such as to be electrically connected to the gate main electrode (50) and overlaps with the active region (3, 103, 203) and the non-active region (4, 104, 204) in plan view.

[C16] The semiconductor device (1, 101, 101a, 201, 201a) according to C15, where the gate main electrode (50) does not overlap with the active region (3, 103, 203) in plan view.

[C17] The semiconductor device (1, 101, 101a, 201, 201a) according to C15 or C16, where the gate pad electrode (70) includes a connecting portion connected to the gate main electrode (50) with a first area in plan view and an electrode surface (73) having a second area exceeding the first area in plan view.

[C18] The semiconductor device (1, 101, 101a, 201, 201a) according to any one of C15 to C17, where the active region (3, 103, 203) includes a plurality of divided regions provided on the semiconductor layer (10), with an interval kept in plan view, and the non-active region (4, 104, 204) includes a portion of the semiconductor layer (10) positioned between the plurality of divided regions in plan view.

[C19] The semiconductor device (1, 101, 101a, 201, 201a) according to C18, where the gate main electrode (50) includes a portion which overlaps with the portion of the non-active region (4, 104, 204) positioned between the plurality of divided regions in plan view, and the gate pad electrode (70) includes a portion which overlaps with the portion of the non-active region (4, 104, 204) positioned between the plurality of divided regions in plan view.

[C20] The semiconductor device (1, 101, 101a, 201, 201a) according to C19, where the gate pad electrode (70) overlaps with the plurality of divided regions in plan view.

[D1] A semiconductor device (1, 101, 101a, 201, 201a) including a semiconductor layer (10) which has a main surface (11) and includes SiC as a main component, a diode structure (290, 291, 292) which is formed in the main surface (11), an insulating layer (61) which is formed on the main surface (11) such as to cover the diode structure (290, 291, 292), a pair of polarizable electrodes (250, 255) which are arranged on the insulating layer (61) and include a first polarizable electrode (250/255) at one side and a second polarizable electrode (255/250) at the other side that are electrically connected to the diode structure (290, 291, 292), and a first polarizable pad electrode (270/275) which is arranged on the first polarizable electrode (250/255) such as to be connected to the first polarizable electrode (250/255) and includes a first connecting portion connected to the first polarizable electrode (250/255) with a first area in plan view and a first electrode surface (272/278) having a second area exceeding the first area in plan view.

[D2] The semiconductor device (1, 101, 101a, 201, 201a) according to D1, where the second area of the first polarizable pad electrode (270/275) exceeds an area of the first polarizable electrode (250/255) in plan view.

[D3] The semiconductor device (1, 101, 101a, 201, 201a) according to D1 or D2, further including a second polarizable pad electrode (275/270) which includes a second connecting portion arranged on the second polarizable electrode (255/250) such as to be connected to the second polarizable electrode (255/250) and connected to the second polarizable electrode (255/250) in a third area in plan view and a second electrode surface (278/272) having a fourth area exceeding the third area.

[D4] The semiconductor device (1, 101, 101a, 201, 201a) according to D3, where the fourth area of the second polarizable pad electrode (275/270) exceeds an area of the second polarizable electrode (255/250) in plan view.

[D5] The semiconductor device (1, 101, 101a, 201, 201a) according to any one of D1 to D4, where the diode structure (290, 291, 292) includes a polysilicon layer, a first conductive type first region (291/292) formed in the polysilicon layer, and a second conductive type second region (292/291) formed in the polysilicon layer such as to form a pn junction portion with the first region (291/292), the first polarizable electrode (250/255) is electrically connected to the first region (291/292) of the diode structure (290, 291, 292), and the second polarizable electrode (255/250) is electrically connected to the second region (292/291) of the diode structure (290, 291, 292).

[D6] The semiconductor device (1, 101, 101a, 201, 201a) according to D5, further including a recess (293) formed in the main surface (11) and in which the diode structure (290, 291, 292) is arranged inside the recess (293).

[D7] The semiconductor device (1, 101, 101a, 201, 201a) according to D6, where the diode structure (290, 291, 292) has an upper end positioned on a bottom wall side of the recess (293) with respect to the main surface (11).

[D8] The semiconductor device (1, 101, 101a, 201, 201a) according to any one of D1 to D7, further including an active region (3, 103, 203) provided on the semiconductor layer (10), a non-active region (4, 104, 204) of the semiconductor layer (10) provided in a region outside the active region (3, 103, 203), and a gate structure (21) formed in the active region (3, 103, 203).

[D9] The semiconductor device (1, 101, 101a, 201, 201a) according to D8, where the diode structure (290, 291, 292) is formed in the non-active region (4, 104, 204).

[D10] The semiconductor device (1, 101, 101a, 201, 201a) according to anyone of D1 to D9, where the diode structure (290, 291, 292) functions as a temperature sensitive diode.

Further, each of the preferred embodiments may be changed, replaced, added or omitted in various ways in the scope of the claims or in the scope of its equivalents. The present invention can be used as a semiconductor device, a semiconductor package, etc., as industrial applicability.

### REFERENCE SIGNS LIST

1 semiconductor device
3 active region
4 non-active region
0 semiconductor layer
11 first main surface (main surface)
21 trench gate structure (gate structure)
50 main surface gate electrode (gate main electrode)
55 main surface source electrode (current conductive electrode)
61 lower insulating layer (insulating layer)
62 side insulating layer (first resin layer)
63 upper insulating layer (first resin layer)
65 end insulating layer (first resin layer)
70 gate pad (gate pad electrode)
73 upper surface of gate pad (electrode surface)
75 source pad (source pad electrode)
76 upper surface of source pad (electrode surface)
80 mold layer (second resin layer)
101 semiconductor device
101a semiconductor device
201 semiconductor device
201a semiconductor device
250 anode electrode (first polarizable electrode)
255 cathode electrode (second polarizable electrode)
290 diode (diode structure)
293 recessed portion (recess)

1. A semiconductor device comprising:
a semiconductor layer which has a main surface and includes SiC as a main component;
a gate structure which is formed in the main surface;
an insulating layer which is formed on the main surface such as to cover the gate structure;
a gate main electrode which is arranged on the insulating layer and electrically connected to the gate structure; and
a gate pad electrode which is arranged on the gate main electrode such as to be connected to the gate main electrode and includes a connecting portion connected to the gate main electrode with a first area in plan view and an electrode surface having a second area exceeding the first area in plan view.

2. The semiconductor device according to claim 1, wherein the electrode surface of the gate pad electrode is exposed to the outside.

3. The semiconductor device according to claim 1, wherein the gate main electrode is formed in a line on the insulating layer.

4. The semiconductor device according to claim 1, wherein the second area of the electrode surface exceeds an area of the gate main electrode.

5. The semiconductor device according to claim 1, further comprising:
an active region provided on the semiconductor layer and; and
a non-active region provided in a region of the semiconductor layer outside the active region;
wherein the gate structure is formed in the active region,
the gate main electrode is formed in the non-active region in plan view, and
the gate pad electrode overlaps with the active region and the non-active region in plan view.

6. The semiconductor device according to claim 1, further comprising:
a current conductive electrode which is arranged on the insulating layer, with an interval kept from the gate main electrode.

7. The semiconductor device according to claim 6, wherein the gate pad electrode overlaps with a part of the current conductive electrode in plan view.

8. The semiconductor device according to claim 6, further comprising:
a current conductive pad electrode which is arranged on the current conductive electrode.

9. The semiconductor device according to claim 8, wherein the current conductive pad electrode overlaps with a part of the gate main electrode in plan view.

10. The semiconductor device according to claim 8, wherein the current conductive pad electrode includes an electrode surface having a third area exceeding the second area of the gate pad electrode in plan view.

11. The semiconductor device according to claim 1, further comprising:
a first resin layer which partially covers the gate main electrode such as to expose a part of the gate main electrode on the insulating layer;
wherein the gate pad electrode is arranged on a portion of the gate main electrode which is exposed from the first resin layer.

12. The semiconductor device according to claim 11, further comprising:
a second resin layer which partially covers the first resin layer such as to expose a part of the gate main electrode on the insulating layer;
wherein the gate pad electrode is arranged on a portion of the gate main electrode which is exposed from the first resin layer and the second resin layer.

13. The semiconductor device according to claim 12, wherein the first resin layer is constituted of a photosensitive resin layer and the second resin layer is constituted of a thermosetting resin layer.

14. The semiconductor device according to claim 1, wherein the gate structure is constituted of a trench gate structure.

15. A semiconductor device comprising:
a semiconductor layer which has a main surface;
an active region which is provided on the semiconductor layer;
a non-active region which is provided in a region of the semiconductor layer outside the active region;
a plurality of gate structures which are formed in the active region;
an insulating layer which is formed on the main surface such as to cover the plurality of gate structures;
a gate main electrode which is arranged on the insulating layer such as to be electrically connected to the plurality of gate structures and overlaps with the non-active region in plan view; and
a gate pad electrode which is arranged on the gate main electrode such as to be electrically connected to the gate main electrode and overlaps with the active region and the non-active region in plan view.

16. The semiconductor device according to claim 15, wherein the gate main electrode is formed in a line in plan view.

17. The semiconductor device according to claim 15, wherein the gate pad electrode includes a connecting portion connected to the gate main electrode with a first area in plan view and an electrode surface having a second area exceeding the first area in plan view.

18. The semiconductor device according to claim 15, wherein the active region includes a plurality of divided regions provided on the semiconductor layer, with an interval kept in plan view, and
the non-active region includes a portion of the semiconductor layer positioned between the plurality of divided regions in plan view.

19. The semiconductor device according to claim 18, wherein the gate main electrode includes a portion which overlaps with a portion of the non-active region positioned between the plurality of divided regions in plan view, and
the gate pad electrode includes a portion which overlaps with a portion of the non-active region positioned between the plurality of divided regions in plan view.

20. The semiconductor device according to claim 19, wherein the gate pad electrode overlaps with the plurality of divided regions in plan view.
